(19) United States
(12) Patent Application Publication
(10) Pub. No.: US 2020/0109305 A1
(43) Pub. Date: Apr. 9, 2020

(54) KIT, LAMINATE, METHOD FOR PRODUCING LAMINATE, METHOD FOR PRODUCING CURED PRODUCT PATTERN, AND METHOD FOR PRODUCING CIRCUIT BOARD

(71) Applicant: FUJIFILM Corporation, Tokyo (JP)

(72) Inventors: Yuichiro GOTO, Haibara-gun (JP); Naoya SHIMOJU, Haibara-gun (JP)

(73) Assignee: FUJIFILM Corporation, Tokyo (JP)

(21) Appl. No.: 16/710,223

(22) Filed: Dec. 11, 2019

Related U.S. Application Data
(63) Continuation of application No. PCT/JP2018/022179, filed on Jun. 11, 2018.

(30) Foreign Application Priority Data
Jun. 14, 2017 (JP) 2017-116959

(51) Int. Cl. C09D 11/38; C09D 11/101; C09D 11/107; H05K 3/00; H01L 21/48; G03F 7/00

(52) U.S. Cl. CPC C09D 11/38; C09D 11/101; G03F 7/0002; H05K 3/0014; H01L 21/481; C09D 11/107

(57) ABSTRACT

Provided are: a kit of a composition for forming an underlayer film for imprints and a curable composition for imprints, which is capable of forming a uniform underlayer film, while having excellent wettability; and a laminate, a method for producing a laminate, a method for producing a cured product pattern, and a method for producing a circuit board, each of which uses the above-mentioned kit. The present invention relates to a kit including a curable composition for imprints and a composition for forming an underlayer film for imprints, in which the composition for forming an underlayer film for imprints contains a solvent in a proportion of 99.0% by mass or more; the surface tension of the curable composition for imprints and the surface tension of the non-volatile component in the composition for forming an underlayer film for imprints satisfy a predetermined relationship; and the non-volatile component has a boiling point of higher than 300° C. and is liquid at 23° C.

### CROSS-REFERENCE TO RELATED APPLICATIONS

This application is a Continuation of PCT International Application No. PCT/JP2018/022179 filed on Jun. 11, 2018, which claims priority under 35 U.S.C § 119(a) to Japanese Patent Application No. 2017-116959 filed on Jun. 14, 2017. Each of the above application(s) is hereby expressly incorporated by reference, in its entirety, into the present application.

### BACKGROUND OF THE INVENTION

### 1. Field of the Invention

The present invention relates to a kit, a laminate, a method for producing a laminate, a method for producing a cured product pattern, and a method for producing a circuit board.

### 2. Description of the Related Art

Imprinting is a technique advanced from an embossing technique well known in the art of optical disc production, which includes pressing a mold prototype with a concave-convex pattern formed on its surface (this is generally referred to as “mold”, “stamper”, “template”, or the like) against a resist to thereby accurately transfer a fine pattern onto the resist through mechanical deformation of the resist. In this technique, in a case where a mold is prepared once, microstructures such as nanostructures can then be easily and repeatedly molded. Therefore, imprinting is a nanofabrication technique that is economical and has few harmful wastes and discharges. Accordingly, in recent years, it has been anticipated that imprinting will be applied to various technical fields.

Imprinting is a method of transferring a fine pattern onto a photo-cured product, by allowing a curable composition to photo-cure under light irradiation through a light-transmissive mold or a light-transmissive substrate, and then separating the mold. This method is applicable to the field of high-precision processing for forming ultrafine patterns such as fabrication of semiconductor integrated circuits, since the imprinting may be implemented at room temperature. In recent years, new trends in development of nano-casting based on a combination of advantages of both, and reversal imprinting capable of creating a three-dimensional laminated structure have been reported.

Such imprinting is used for a purpose of processing a substrate by a method such as etching using a formed pattern as a mask. By virtue of high precision alignment and a high degree of integration, such a technique can replace a conventional lithographic technique in fabrication of high-density semiconductor integrated circuits, fabrication of transistors in liquid crystal displays, and magnetic processing for next-generation hard disks referred to as patterned media. Efforts to use imprinting practically in these applications have recently become active.

On the other hand, with progress of activities in imprinting, adhesiveness between the substrate and the curable composition for imprints has come to be regarded as a problem. In imprinting, the curable composition for imprints is applied over the surface of the substrate, the curable composition for imprints is allowed to cure under light irradiation, in a state of the surface of the substrate being in contact with a mold, and then the mold is separated. In the step of separating the mold, there may be a case where the cured product is separated from the substrate and unfortunately adheres to the mold. This is thought to be because the adhesiveness between the substrate and the cured product is lower than the adhesiveness between the mold and the cured product. As a solution to this problem, use of an adhesion film for imprints using an adhesive composition for imprints that improves the adhesiveness between the substrate and the cured product has been studied (for example, JP2016-028419A).

In addition, in a case where an imprint pattern is used as an etching mask, it is important to ensure the uniformity of a concave portion (residual film) of the imprint pattern. In a case where the residual film uniformity is low, etching unevenness occurs during an etching process, and it becomes difficult to carry out pattern transfer with uniformity and good rectangularity on the entire surface of the etched portion.

In addition, in a case where the curable composition for imprints is applied by an ink jet (IJ) method, a technique for improving the wet spreading of ink jet liquid droplets has been studied (for example, JP2017-055108A).

### SUMMARY OF THE INVENTION

However, it may be difficult to form a uniform pattern depending on the composition for forming an underlayer film for imprints. Specifically, particularly in a case where a curable composition for imprints is applied by an ink jet (IJ) method, for example, as shown in FIG. 2, in a case where liquid droplets of a curable composition 22 for imprints are added dropwise on the surface of an underlayer film 21 at equal intervals and brought into contact with a mold, the liquid droplets spread on the underlayer film 21 to become a film-like curable composition 22 for imprints. However, in a case where the curable composition for imprints does not spread uniformly, a region where the film thickness of the curable composition 22 for imprints is thin may occur on the underlayer film 21. In a case where etching is carried out in such a pattern, etching unevenness occurs in the thin region and other regions, and it becomes difficult to etch and transfer a desired pattern shape over the entire imprint region. In addition, as a result of extensive studies on known techniques by the present inventors, there was a case where the wet spreading of the curable composition for imprints is insufficient or a case where the composition of the cured film becomes non-uniform, consequently regions having different etching resistance are generated in the film surface, making it difficult to use the imprint pattern as an etching mask. That is, there is a need for a kit in which the curable composition for imprints spreads uniformly on the underlayer film 21.

The present invention has been made to solve such problems, and an object of the present invention is to provide a kit of a composition for forming an underlayer film for imprints and a curable composition for imprints, which is capable of forming an imprint pattern having excellent residual film uniformity, as well as a laminate, a method for producing a laminate, a method for producing a cured product pattern, and a method for producing a circuit board, each of which uses the above-mentioned kit.

Based on the above problems, it has been found that the foregoing object can be achieved in a case where the surface tension of a non-volatile component in the composition for forming an underlayer film for imprints and the surface tension of the curable composition for imprints are set to have a predetermined relationship, and ΔHSP, which is a distance between Hansen solubility parameters of the non-volatile component in the composition for forming an underlayer film for imprints and the curable composition for imprints, is made to satisfy a predetermined relationship. Specifically, the foregoing object has been achieved by the following means <1>, preferably <2> to <16>.

<1> A kit comprising a curable composition for imprints and a composition for forming an underlayer film for imprints, the kit satisfying all of the following A to C;

A: the composition for forming an underlayer film for imprints contains a compound that is liquid at 23° C. and has a boiling point of 300° C. or lower in a proportion of 99.0% by mass or more;

B: any of the following (1) to (3) is satisfied;

γUL−γResist≥3 and |ΔHSP|≤0.5, (1)

γUL−γResist≥5 and |ΔHSP|≤1.0, (2)

γUL−γResist≥6 and |ΔHSP|≤3.0, (3)

in the above formulae, γResist represents a surface tension at 23° C. of the curable composition for imprints, and γUL represents a surface tension at 23° C. of a composition comprised of the components excluding the compound that is liquid at 23° C. and has a boiling point of 300° C. or lower, in the composition for forming an underlayer film for imprints;

ΔHSP=(4.0×ΔD²+ΔP²+ΔH²)^{0.5}

in which the ΔD is a difference between a dispersion term component of a Hansen solubility parameter vector of a component having the highest content in the curable composition for imprints and a dispersion term component of a Hansen solubility parameter vector of a component having the highest content in the composition comprised of the components excluding the compound that is liquid at 23° C. and has a boiling point of 300° C. or lower, in the composition for forming an underlayer film for imprints; the ΔP is a difference between a polar term component of a Hansen solubility parameter vector of the component having the highest content in the curable composition for imprints and a polar term component of a Hansen solubility parameter vector of the component having the highest content in the composition comprised of the components excluding the compound that is liquid at 23° C. and has a boiling point of 300° C. or lower, in the composition for forming an underlayer film for imprints; and the ΔH is a difference between a hydrogen bond term component of a Hansen solubility parameter vector of the component having the highest content in the curable composition for imprints and a hydrogen bond term component of a Hansen solubility parameter vector of the component having the highest content in the composition comprised of the components excluding the compound that is liquid at 23° C. and has a boiling point of 300° C. or lower, in the composition for forming an underlayer film for imprints,

C: the component having the highest content in the composition comprised of the components excluding the compound that is liquid at 23° C. and has a boiling point of 300° C. or lower, in the composition for forming an underlayer film for imprints, has a boiling point of higher than 300° C. and is liquid at 23° C.

<2> The kit according to <l>, in which at least one contained in the composition comprised of the components excluding the compound that is liquid at 23° C. and has a boiling point of 300° C. or lower, in the composition for forming an underlayer film for imprints, is a compound having a group capable of reacting with the curable composition for imprints to form a covalent bond.

<3> The kit according to <1>, in which the component having the highest content in the composition comprised of the components excluding the compound that is liquid at 23° C. and has a boiling point of 300° C. or lower, in the composition for forming an underlayer film for imprints, is a compound having a group capable of reacting with the curable composition for imprints to form a covalent bond.

<4> The kit according to <2> or <3>, in which at least one of the compounds having a group capable of reacting with the curable composition for imprints to form a covalent bond is a compound containing an aromatic ring structure.

<5> The kit according to any one of <1> to <4>, in which the γUL is 38.0 mN/m or more.

<6> The kit according to any one of <1> to <5>, in which a viscosity at 23° C. of the composition comprised of the components excluding the compound that is liquid at 23° C. and has a boiling point of 300° C. or lower, in the composition for forming an underlayer film for imprints, is 5 to 1000 mPa·s.

<7> The kit according to any one of <1> to <6>, in which a difference between an Ohnishi parameter of the composition comprised of the components excluding the compound that is liquid at 23° C. and has a boiling point of 300° C. or lower, in the composition for forming an underlayer film for imprints, and an Ohnishi parameter of the curable composition for imprints is 0.5 or less; provided that the Ohnishi parameter is the sum of the number of carbon atoms, hydrogen atoms and oxygen atoms/(number of carbon atoms-number of oxygen atoms) for atoms constituting each composition.

<8> The kit according to any one of <1> to <7>, in which the component having the highest content among the compounds that are liquid at 23° C. and have a boiling point of 300° C. or lower, in the composition for forming an underlayer film for imprints, has a boiling point of 130° C. or lower.

<9> The kit according to any one of <1> to <8>, in which the composition for forming an underlayer film for imprints contains a photopolymerization initiator.

<10> The kit according to any one of <1> to <9>, in which the component having the highest content in the composition comprised of the components excluding the compound that is liquid at 23° C. and has a boiling point of 300° C. or lower, in the composition for forming an underlayer film for imprints, has a boiling point of 325° C. or higher.

<11> A laminate formed from the kit according to any one of <1> to <10>, comprising:

an underlayer film formed from the composition for forming an underlayer film for imprints; and

an imprint layer formed from the curable composition for imprints and positioned on a surface of the underlayer film.

<12> A method for producing a laminate using the kit according to any one of <1> to <10>, the method comprising:

applying the curable composition for imprints onto a surface of the underlayer film formed from the composition for forming an underlayer film for imprints.

<13> The method for producing a laminate according to <12>, in which the curable composition for imprints is applied onto the surface of the underlayer film by an ink jet method.

<14> The method for producing a laminate according to <12> or <13>, further comprising:

a step of applying the composition for forming an underlayer film for imprints in a layered manner on a substrate; and

a step of heating the composition for forming an underlayer film for imprints applied in a layered manner at 40° C. to 70° C.

<15> A method for producing a cured product pattern, using the kit according to any one of <1> to <10>, the method comprising:

an underlayer film forming step of applying a composition for forming an underlayer film for imprints onto a substrate to form an underlayer film;

an applying step of applying a curable composition for imprints onto a surface of the underlayer film;

a mold contact step of bringing the curable composition for imprints into contact with a mold having a pattern for transferring a pattern shape;

a light irradiation step of irradiating the curable composition for imprints with light to form a cured product; and

a mold release step of separating the cured product and the mold from each other.

<16> A method for producing a circuit board, comprising:

a step of obtaining a cured product pattern by the production method according to <15>.

According to the present invention, it has become possible to provide a kit of a composition for forming an underlayer film for imprints and a curable composition for imprints, which is capable of forming an imprint pattern having excellent residual film uniformity, as well as a laminate, a method for producing a laminate, a method for producing a cured product pattern, and a method for producing a circuit board, each of which uses the above-mentioned kit.

### BRIEF DESCRIPTION OF THE DRAWINGS

FIG. 1 shows an example of a production process in a case where a cured product pattern is formed and the obtained cured product pattern is used for processing a substrate by etching.

FIG. 2 is a schematic view showing a state of wet spreading of a curable composition for imprints in a case where the curable composition for imprints is applied onto a surface of an underlayer film having low wettability by an ink jet method.

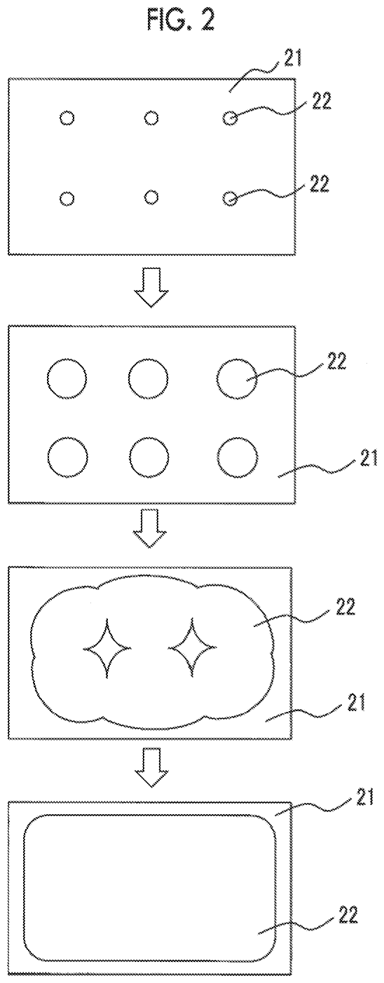

### DESCRIPTION OF THE PREFERRED EMBODIMENTS

Hereinafter, the contents of the present invention will be described in detail. In the present specification, the numerical ranges shown with “to” means ranges including the numerical values indicated before and after “to” as a lower limit value and an upper limit value, respectively.

In the present specification, the term “(meth)acrylate” represents acrylate and methacrylate.

In the present specification, the term “imprint” preferably refers to pattern transfer in a size of 1 nm to 10 mm and more preferably pattern transfer (nanoimprint) in a size of approximately 10 nm to 100 μm.

In the description of a group (atomic group) in the present specification, the description with no indication of “substituted” or “unsubstituted” includes both a group (atomic group) having a substituent and a group (atomic group) not having a substituent. For example, the term “alkyl group” includes not only an alkyl group not having a substituent (unsubstituted alkyl group) but also an alkyl group having a substituent (substituted alkyl group).

In the present specification, the term “light” includes not only light in wavelength regions of ultraviolet, near ultraviolet, far ultraviolet, visible light and infrared, and electromagnetic waves, but also radiation rays. The radiation rays include microwaves, electron beams, extreme ultraviolet (EUV), and X-rays. Laser light such as a 248 nm excimer laser, a 193 nm excimer laser, and a 172 nm excimer laser can also be used. These sorts of light may be monochromatic light (single wavelength light) that has passed through an optical filter, or may be light that has a plurality of different wavelengths (complex light).

Unless otherwise specified, the weight-average molecular weight (Mw) in the present invention refers to a value as measured by gel permeation chromatography (GPC).

The boiling point in the present invention refers to a boiling point at 1 atmosphere (1 atm=1013.25 hPa).

The kit according to the embodiment of the present invention is a kit having a curable composition for imprints and a composition for forming an underlayer film for imprints, and is characterized by satisfying all of the following A to C.

A: the composition for forming an underlayer film for imprints contains a compound that is liquid at 23° C. and has a boiling point of 300° C. or lower (hereinafter, also referred to as “solvent”) in a proportion of 99.0% by mass or more;

B: any of the following (1) to (3) is satisfied;

γUL−γResist≥3 and |ΔHSP|≤0.5, (1)

γUL−γResist≥5 and |ΔHSP|≤1.0, (2)

γUL−γResist≥6 and |ΔHSP|≤3.0, (3)

in the above formulae, γResist represents a surface tension at 23° C. of the curable composition for imprints, and γUL represents a surface tension at 23° C. of a composition comprised of the components (hereinafter, also referred to as “non-volatile component”) excluding the compound that is liquid at 23° C. and has a boiling point of 300° C. or lower, in the composition for forming an underlayer film for imprints;

ΔHSP=(4.0×ΔD²+ΔP²+ΔH²)^{0.5}

in which the ΔD is a difference between a dispersion term component of a Hansen solubility parameter vector of a component having the highest content in the curable composition for imprints and a dispersion term component of a Hansen solubility parameter vector of a component having the highest content in the composition comprised of the components excluding the compound that is liquid at 23° C. and has a boiling point of 300° C. or lower, in the composition for forming an underlayer film for imprints; the ΔP is a difference between a polar term component of a Hansen solubility parameter vector of the component having the highest content in the curable composition for imprints and a polar term component of a Hansen solubility parameter vector of the component having the highest content in the composition comprised of the components excluding the compound that is liquid at 23° C. and has a boiling point of 300° C. or lower, in the composition for forming an underlayer film for imprints; and the ΔH is a difference between a hydrogen bond term component of a Hansen solubility parameter vector of the component having the highest content in the curable composition for imprints and a hydrogen bond term component of a Hansen solubility parameter vector of the component having the highest content in the composition comprised of the components excluding the compound that is liquid at 23° C. and has a boiling point of 300° C. or lower, in the composition for forming an underlayer film for imprints,

C: the component having the highest content in the composition comprised of the components excluding the compound that is liquid at 23° C. and has a boiling point of 300° C. or lower, among the components having the highest content in the composition for forming an underlayer film for imprints, has a boiling point of higher than 300° C. and is liquid at 23° C.

By adopting such a configuration, a uniform underlayer film can be formed and this underlayer film can be made excellent in the wettability of the curable composition for imprints. The reason for this is considered to be due to the fact that, in a case where the surface tension of the non-volatile component in the composition for forming an underlayer film for imprints and the surface tension of the curable composition for imprints are set to have a predetermined relationship, wet spreading of the curable composition for imprints to the surface of the underlayer film, in particular, the speed of wet spreading is increased, and in a case where the ΔHSP between the curable composition for imprints and the non-volatile component in the composition for forming an underlayer film for imprints is made to satisfy a predetermined relationship, the compatibility of the underlayer film and the imprint layer formed from the curable composition for imprints is improved, thus making compatible therebetween.

Furthermore, the cured product pattern obtained from the kit according to the embodiment of the present invention can provide a pattern with excellent residual film uniformity and excellent etching resistance.

<Composition for Forming Underlayer Film for Imprints>

The composition for forming an underlayer film for imprints used in the present invention contains a compound (solvent) that is liquid at 23° C. and has a boiling point of 300° C. or lower in a proportion of 99.0% by mass or more, and further contains a composition (non-volatile component) comprised of the components excluding the solvent. Usually, the non-volatile component finally forms the underlayer film.

<Non-Volatile Component>>

Among the non-volatile components contained in the composition for forming an underlayer film for imprints, the component having the highest content has a boiling point of higher than 300° C. and is liquid at 23° C. By adopting such a configuration, the underlayer film obtained becomes a liquid and therefore it becomes possible to improve the wettability of the curable composition for imprints. Furthermore, such a non-volatile component is usually in a liquid state at normal temperature (for example, 23° C.) and does not volatilize easily by heating. Therefore, an underlayer film in a liquid state at room temperature can be formed. In a case where there are two or more components having the highest content, it is sufficient that at least one thereof has a boiling point of higher than 300° C. and is liquid at 23° C.

In addition, in a case where there are two or more components having the highest content among the non-volatile components, the component having the highest surface tension at 23° C. is defined as the component having the highest content among the non-volatile components in the present invention.

In the present invention, preferably 90% by mass or more, more preferably 93% by mass or more, still more preferably 95% by mass or more, even still more preferably 97% by mass or more, and particularly preferably 99% by mass or more of the non-volatile component is the compound that has a boiling point of higher than 300° C. and is liquid at 23° C.

The boiling point of the component having the highest content among the non-volatile components is higher than 300° C., preferably 310° C. or higher, more preferably 325° C. or higher, and still more preferably 330° C. or higher. By setting the boiling point of the component having the highest content to 300° C. or higher, particularly 325° C. or higher, it is possible to effectively suppress volatilization of the composition in a case where the composition for forming an underlayer film for imprints is layered, and the film thickness stability of the resulting underlayer film tends to be further improved. Furthermore, it becomes possible to further improve the wettability and residual film uniformity. The upper limit of the boiling point is not particularly defined, but can be, for example, 700° C. or lower, further 600° C. or lower, and particularly 500° C. or lower.

The viscosity of the non-volatile component in the composition for forming an underlayer film for imprints is preferably 5 mPa·s or more, more preferably 7 mPa·s or more, still more preferably 8 mPa·s or more, and even still more preferably 9 mPa·s or more. The viscosity is preferably 1500 mPa·s or less, more preferably 1000 mPa·s or less, still more preferably 500 mPa·s or less, and even still more preferably 150 mPa·s or less.

By setting the viscosity to 5 mPa·s or more, the coating film stability of the underlayer film is improved, and therefore the film thickness stability tends to be improved. By setting the viscosity to 1500 mPa·s or less, particularly 1000 mPa·s or less, the wettability of the curable composition for imprints and the residual film uniformity can be further improved.

The above-mentioned viscosity refers to the viscosity of a mixture of non-volatile components in a case where two or more non-volatile components are contained.

The viscosity is measured according to the method described in the Examples which will be described later. In a case where it is difficult to obtain the devices described in the Examples due to discontinued production or the like, other devices having the same performance can be used (hereinafter, the same applies to the methods described in the Examples).

The surface tension (γUL) at 23° C. of the non-volatile component in the composition for forming an underlayer film for imprints is preferably 35.0 mN/m or more, more preferably 37.0 mN/m or more, still more preferably 38.0 mN/m or more, even still more preferably 39.0 mN/m or more, and particularly preferably 40.0 mN/m or more. The upper limit of the surface tension is not particularly defined, but is preferably, for example, 50.0 mN/m or less, more preferably 47.0 mN/m or less, and still more preferably 45.0 mN/m or less, and may be 43.0 mN/m or less. By setting the surface tension γUL to 35.0 mN/m or more, particularly 38.0 mN/m or more, a sufficient difference in surface tension from the curable composition for imprints can be secured, and therefore better residual film uniformity can be achieved.

The surface tension of the non-volatile component is measured according to the method described in the Examples which will be described later.

The dispersion term component of the Hansen solubility parameter (HSP) vector of the component having the highest content among the non-volatile components is preferably 14.0 or more, more preferably 15.0 or more, and still more preferably 16.0 or more. The dispersion term component is preferably 20.0 or less, more preferably 19.0 or less, still more preferably 18.5 or less, even still more preferably 18.2 or less, and particularly preferably 18.0 or less.

The polar term component of the HSP vector of the non-volatile component is preferably 3.5 or more, more preferably 3.8 or more, still more preferably 4.0 or more, and particularly preferably 4.3 or more. The polar term component is preferably 8.0 or less, more preferably 6.0 or less, still more preferably 5.5 or less, and particularly preferably 5.0 or less.

The hydrogen bond term component of the HSP vector of the non-volatile component is preferably 4.0 or more, more preferably 4.7 or more, still more preferably 5.2 or more, and particularly preferably 5.5 or more. The hydrogen bond term component is preferably 8.0 or less, more preferably 7.0 or less, still more preferably 6.7 or less, and particularly preferably 6.5 or less.

The dispersion term component, polar term component, and hydrogen bond term component of the HSP vector of the non-volatile component are each measured according to the method described in the Examples which will be described later.

The Ohnishi parameter of the non-volatile component is preferably 5.0 or less, more preferably 4.0 or less, and still more preferably 3.5 or less. The lower limit value of the Ohnishi parameter of the non-volatile component is not particularly defined, but may be, for example, 2.5 or more, further 3.0 or more. The Ohnishi parameter is calculated according to the method described in the Examples which will be described later.

The proportion of the non-volatile component in the composition for forming an underlayer film for imprints is preferably 1% by mass or less, more preferably 0.5% by mass or less, and may be 0.4% by mass or less. Only one type of non-volatile component may be contained, or two or more types of non-volatile components may be contained.

In a case where two or more types of non-volatile components are contained, the total amount thereof is preferably within the above range.

<<<Compound Having Reactive Group>>>

At least one of the non-volatile components in the composition for forming an underlayer film for imprints is preferably a compound having a group capable of reacting with the curable composition for imprints to form a covalent bond (hereinafter, also simply referred to as “compound having a reactive group”). By adopting such a configuration, the pattern strength of the imprinted cured product can be maintained even in a case where the composition for forming an underlayer film for imprints is mixed with the curable composition for imprints.

The compound having a reactive group is preferably the component having the highest content among the non-volatile components. In addition, preferably 90% by mass or more, more preferably 93% by mass or more, still more preferably 95% by mass or more, and even still more preferably 99% by mass or more of the non-volatile components is the compound having a reactive group. Therefore, the compound having a reactive group preferably satisfies the viscosity and/or boiling point described in the section of

### <<Non-Volatile Component>>.

The compound having a reactive group contained in the non-volatile component may be only one type or may be two or more types. In a case where two or more types of the compounds having a reactive group are contained, the total amount thereof is preferably within the above range.

It is sufficient that the reactive group capable of reacting with the curable composition for imprints forms a covalent bond with at least one component of the curable composition for imprints. Examples of such a reactive group include crosslinkable groups, such as an ethylenically unsaturated group (referring to a group containing an ethylenically unsaturated bond) and an epoxy group, among which an ethylenically unsaturated group is preferable. Examples of the ethylenically unsaturated group include a (meth)acryloyl group and a vinyl group, among which a (meth)acryloyl group is more preferable and an acryloyl group is still more preferable. The (meth)acryloyl group is preferably a (meth)acryloyloxy group. The compound having a reactive group may contain two or more types of reactive groups in one molecule, or may contain two or more reactive groups of the same type in one molecule. The compound having a reactive group is preferably a compound containing one to three reactive groups in one molecule, and more preferably a compound containing two reactive groups in one molecule.

In addition, the compound having the reactive group capable of reacting with the curable composition for imprints preferably have a molecular weight of 200 to 1,000 and more preferably 200 to 900.

In addition, it is preferable that the compound having the reactive group capable of reacting with the curable composition for imprints are a compound containing an aromatic ring structure.

The aromatic ring structure in the compound containing an aromatic ring structure is exemplified by an aromatic ring structure containing at least one of a benzene ring or a naphthalene ring, and an aromatic ring structure containing at least a benzene ring is preferable. The compound containing an aromatic ring structure preferably contains 1 to 4 aromatic rings, more preferably 1 to 3 aromatic rings, and still more preferably 1 or 2 aromatic rings in one molecule. Here, regarding the number of aromatic rings, a fused ring is considered as one ring. In a case where it has an aromatic ring, the surface tension increases and therefore the wettability of the curable composition for imprints on the underlayer film can be further improved.

Examples of the compound having a reactive group used in the present invention include polymerizable compounds described in the section of <Curable composition for imprints> which will be described later, in addition to the compounds used in the Examples which will be described later.

<<<Alkylene Glycol Compound>>>

The non-volatile component may contain an alkylene glycol compound.

The alkylene glycol compound preferably has 3 to 1000 alkylene glycol structural units, more preferably 4 to 500 alkylene glycol structural units, still more preferably 5 to 100 alkylene glycol structural units, and even still more preferably 5 to 50 alkylene glycol structural units.

The weight-average molecular weight (Mw) of the alkylene glycol compound is preferably 150 to 10,000, more preferably 200 to 5,000, still more preferably 300 to 3,000, and even still more preferably 300 to 1,000.

Examples of the alkylene glycol compound include polyethylene glycol, polypropylene glycol, and mono- or dimethyl ether, mono- or dioctyl ether, mono- or dinonyl ether, mono- or didecyl ether, monostearate, monooleate, monoadipate, and monosuccinate thereof, among which polyethylene glycol and polypropylene glycol are preferable.

The surface tension at 23° C. of the alkylene glycol compound is preferably 38 mN/m or more, and more preferably 40 mN/m or more. The upper limit of the surface tension is not specifically defined, but it is, for example, 48 mN/m or less. By blending such a compound, the wettability of the curable composition for imprints provided immediately above the underlayer film can be further improved.

In a case where the alkylene glycol compound is contained, the proportion thereof is 40% by mass or less, preferably 30% by mass or less, more preferably 20% by mass or less, and still more preferably 5 to 15% by mass of the non-volatile component.

Only one type of alkylene glycol compound may be used, or two or more types of alkylene glycol compounds may be used. In a case where two or more types of alkylene glycol compounds are used, the total amount thereof is preferably within the above range.

<<<Polymerization Initiator>>>

The non-volatile component may contain a polymerization initiator. Examples of the polymerization initiator include a thermal polymerization initiator and a photopolymerization initiator. A photopolymerization initiator is preferable from the viewpoint of improving the crosslinking reactivity with the curable composition for imprints. As the photopolymerization initiator, a radical polymerization initiator and a cationic polymerization initiator are preferable, and a radical polymerization initiator is more preferable. In the present invention, a plurality of photopolymerization initiators may be used in combination.

Any of known compounds can be used as the photo-radical polymerization initiator. Examples thereof include a halogenated hydrocarbon derivative (for example, a compound having a triazine skeleton, a compound having an oxadiazole skeleton, or a compound having a trihalomethyl group), an acylphosphine compound such as acylphosphine oxide, hexaarylbiimidazole, an oxime compound such as oxime derivative, an organic peroxide, a thio compound, a ketone compound, an aromatic onium salt, a ketoxime ether, an aminoacetophenone compound, a hydroxyacetophenone, an azo-based compound, an azide compound, a metallocene compound, an organoboron compound, and an iron arene complex. With respect to details thereof, reference can be made to the descriptions in paragraphs [0165] to [0182] of JP2016-027357A, the contents of which are incorporated herein.

The acylphosphine compound may be, for example, 2,4,6-trimethylbenzoyl-diphenyl-phosphine oxide. In addition, IRGACURE-819 and IRGACURE-TPO (trade names: both manufactured by BASF Corporation) which are commercially available products can be used.

In a case of being blended, the content of the photopolymerization initiator used in the composition for forming an underlayer film for imprints is, for example, 0.01% to 15% by mass, preferably 0.1% to 12% by mass, and more preferably 0.2% to 7% by mass in the non-volatile component. In a case where two or more types of photopolymerization initiators are used, the total amount thereof is within the above range.

<<<Other Non-Volatile Components>>>

As the non-volatile component blended in the composition for forming an underlayer film for imprints, one type or two or more types of a thermal polymerization initiator, a polymerization inhibitor, an antioxidant, a leveling agent, a thickener, a surfactant, and the like may be contained in addition to the above-mentioned compounds.

With respect to the thermal polymerization initiator and the like, individual components described in JP2013-036027A, JP2014-090133A, and JP2013-189537A can be used in addition to the components described in the Examples which will be described later. Regarding the content and the like, the description in the above-mentioned patent publications can be referred to.

In the present invention, the composition for forming an underlayer film for imprints can be configured to be substantially free of a surfactant. The phrase “substantially free of” means that the content of the surfactant is 0.1% by mass or less of the non-volatile component in the composition for forming an underlayer film for imprints.

<<Solvent>>

The composition for forming an underlayer film for imprints preferably contains a compound (solvent) that is liquid at 23° C. and has a boiling point of 300° C. or lower in a proportion of preferably 99.0% by mass or more and more preferably 99.5% by mass or more. The proportion of such a compound may be 99.6% by mass or more. In the present invention, the liquid means that the viscosity at 23° C. is 100000 mPa·s or less.

The composition for forming an underlayer film for imprints may contain only one type of solvent, or may contain two or more types of solvents. In a case where two or more types of solvents are contained, the total amount thereof is preferably within the above range.

The boiling point of the component having the highest content among the above solvents is preferably 180° C. or lower, more preferably 160° C. or lower, and still more preferably 130° C. or lower. By setting the boiling point to 180° C. or lower, particularly 130° C. or lower, the solvent can be easily removed from the underlayer film. In the present invention, among the solvents contained in the composition for forming an underlayer film for imprints, preferably 90% by mass or more, more preferably 93% by mass or more, still more preferably 95% by mass or more, and even still more preferably 99% by mass or more thereof is a solvent satisfying the above boiling point.

The solvent is preferably an organic solvent. The solvent is preferably a solvent having any one or more of an ester group, a carbonyl group, a hydroxyl group, and an ether group.

Specific examples of the solvent include propylene glycol monoalkyl ether carboxylate, propylene glycol monoalkyl ether, lactate, acetate, formate, alkoxypropionate, chain ketone, cyclic ketone, lactone, and alkylene carbonate.

The propylene glycol monoalkyl ether carboxylate is preferably at least one selected from the group consisting of propylene glycol monomethyl ether acetate, propylene glycol monomethyl ether propionate, and propylene glycol monoethyl ether acetate, and particularly preferably propylene glycol monomethyl ether acetate.

The propylene glycol monoalkyl ether is preferably propylene glycol monomethyl ether or propylene glycol monoethyl ether.

The lactate is preferably ethyl lactate, butyl lactate, or propyl lactate.

The acetate is preferably methyl acetate, ethyl acetate, butyl acetate, isobutyl acetate, propyl acetate, isoamyl acetate, or 3-methoxybutyl acetate.

The formate is preferably methyl formate, ethyl formate, butyl formate, or propyl formate.

The alkoxypropionate is preferably methyl 3-methoxypropionate (MMP) or ethyl 3-ethoxypropionate (EEP).

The chain ketone is preferably 1-octanone, 2-octanone, 1-nonanone, 2-nonanone, acetone, 4-heptanone, 1-hexanone, 2-hexanone, diisobutylketone, phenylacetone, methyl ethyl ketone, methyl isobutyl ketone, acetylacetone, acetonyl acetone, ionone, diacetonyl alcohol, acetyl carbinol, acetophenone, methyl naphthyl ketone, or methyl amyl ketone.

The cyclic ketone is preferably methylcyclohexanone, isophorone, or cyclohexanone.

The lactone is preferably γ-butyrolactone.

The alkylene carbonate is preferably propylene carbonate.

In addition to the above-mentioned components, it is preferable to use an ester-based solvent having 7 or more carbon atoms (preferably 7 to 14, more preferably 7 to 12, and still more preferably 7 to 10) and 2 or less hetero atoms.

Preferred examples of the ester-based solvent having 7 or more carbon atoms and 2 or less hetero atoms include amyl acetate, 2-methylbutyl acetate, 1-methylbutyl acetate, hexyl acetate, pentyl propionate, hexyl propionate, butyl propionate, isobutyl isobutyrate, heptyl propionate, and butyl butanoate. It is particularly preferable to use isoamyl acetate.

In addition, it is also preferable to use one having a flash point (hereinafter, also referred to as fp) of 37° C. or higher. Such a component is preferably propylene glycol monomethyl ether (fp: 47° C.), ethyl lactate (fp: 53° C.), ethyl 3-ethoxypropionate (fp: 49° C.), methyl amyl ketone (fp: 42° C.), cyclohexanone (fp: 30° C.), pentyl acetate (fp: 45° C.), methyl 2-hydroxyisobutyrate (fp: 45° C.), γ-butyrolactone (fp: 101° C.) or propylene carbonate (fp: 132° C.). Among these, propylene glycol monoethyl ether, ethyl lactate, pentyl acetate, or cyclohexanone is more preferable, and propylene glycol monoethyl ether or ethyl lactate is particularly preferable. Here, the “flash point” refers to a value described in a reagent catalog of Tokyo Chemical Industry Co., Ltd. or Sigma-Aldrich Co. LLC.

A more preferred solvent is at least one selected from the group consisting of water, propylene glycol monomethyl ether acetate (PGMEA), ethoxyethyl propionate, cyclohexanone, 2-heptanone, γ-butyrolactone, butyl acetate, propylene glycol monomethyl ether (PGME), ethyl lactate, and 4-methyl-2-pentanol, and a still more preferred solvent is at least one selected from the group consisting of PGMEA and PGME.

A conventionally known storage container can be used as a storage container for the composition for forming an underlayer film for imprints. In addition, as the storage container, it is also preferable to use a multi-layer bottle in which the inner wall of the container is composed of 6 types and 6 layers of resin, or a bottle having a seven-layer structure of six types of resins, for the purpose of suppressing the incorporation of impurities into raw materials and compositions. Examples of such a container include containers described in JP2015-123351A.

<Curable Composition for Imprints>

Next, the curable composition for imprints used in the present invention will be described.

The curable composition for imprints used in the present invention is not particularly defined, and a known curable composition for imprints can be used and preferably contains at least a polymerizable compound.

In the present invention, it is preferable to design the curable composition for imprints to have a low viscosity and a high surface tension in order to make use of capillary force and enable high-speed filling into a mold pattern.

Specifically, the viscosity at 23° C. of the curable composition for imprints is preferably 20.0 mPa·s or less, more preferably 15.0 mPa·s or less, still more preferably 11.0 mPa·s or less, and even still more preferably 9.0 mPa·s or less. The lower limit value of the viscosity is not particularly limited, but may be, for example, 5.0 mPa·s or more. The viscosity is measured according to the method described in the Examples which will be described later.

In addition, the surface tension (γResist) at 23° C. of the curable composition for imprints is preferably 30 mN/m or more, more preferably 31 mN/m or more, and still more preferably 33 mN/m or more. Use of the curable composition for imprints having a high surface tension leads to an increase in capillary force and enables high speed filling of the curable composition for imprints into a mold pattern. The upper limit value of the surface tension is not particularly limited, but it is preferably 40 mN/m or less and more preferably 38 mN/m or less from the viewpoint of imparting the relationship with the underlayer film and ink jet suitability, and may be 36 mN/m or less.

The present invention is highly significant in that the wettability of a high surface tension curable composition for imprints with high capillary force and good fillability into mold pattern, but poor wettability with the underlayer film can be improved by using a predetermined underlayer film.

The surface tension at 23° C. of the curable composition for imprints is measured according to the method described in the Examples which will be described later.

The dispersion term component of the HSP vector of the curable composition for imprints is preferably 14.0 or more, more preferably 15.0 or more, still more preferably 16.0 or more, and particularly preferably 17.0 or more. The dispersion term component is preferably 20.0 or less, more preferably 19.0 or less, still more preferably 18.5 or less, even still more preferably 18.2 or less, and particularly preferably 18.0 or less.

The polar term component of the HSP vector of the curable composition for imprints is preferably 3.5 or more, more preferably 3.8 or more, still more preferably 4.0 or more, and particularly preferably 4.3 or more. The polar term component is preferably 8.0 or less, more preferably 6.0 or less, still more preferably 5.0 or less, and even still more preferably 4.7 or less.

The hydrogen bond term component of the HSP vector of the curable composition for imprints is preferably 4.0 or more, more preferably 4.7 or more, still more preferably 5.2 or more, and particularly preferably 5.5 or more. The hydrogen bond term component is preferably 8.0 or less, more preferably 7.0 or less, still more preferably 6.5 or less, and even still more preferably 6.0 or less.

The dispersion term component, polar term component, and hydrogen bond term component of the HSP vector of the curable composition for imprints are each measured according to the method described in the Examples which will be described later.

The Ohnishi parameter of the curable composition for imprints is preferably 5.0 or less, more preferably 4.0 or less, and still more preferably 3.5 or less. The lower limit value of the Ohnishi parameter of the non-volatile component is not particularly defined, but may be, for example, 2.5 or more, or 3.0 or more. The Ohnishi parameter is calculated according to the method described in the Examples which will be described later.

In the present invention, the content of the solvent in the curable composition for imprints is preferably 5% by mass or less, more preferably 3% by mass or less, and still more preferably 1% by mass or less of the curable composition for imprints.

In addition, the curable composition for imprints used in the present invention can also be made into an aspect which is substantially free of a polymer (a polymer having a weight-average molecular weight of preferably more than 1,000, more preferably more than 2000, and still more preferably 10,000 or more). The phrase “substantially free of a polymer” means, for example, that the polymer content is 0.01% by mass or less of the curable composition for imprints. It is preferable that the polymer content is 0.005% by mass or less, and it is more preferable that the curable composition for imprints contains no polymer at all.

<<Polymerizable Compound>>

The polymerizable compound contained in the curable composition for imprints used in the present invention may be a monofunctional polymerizable compound, a polyfunctional polymerizable compound, or a mixture of both. In addition, at least a part of the polymerizable compound contained in the curable composition for imprints is preferably liquid at 23° C., and more preferably 15% by mass or more of the polymerizable compound contained in the curable composition for imprints is liquid at 23° C.

The polymerizable compound preferably contains a ring structure, and more preferably contains an aromatic ring structure.

The type of the monofunctional polymerizable compound used in the curable composition for imprints is not particularly defined unless departing from the spirit of the present invention.

The molecular weight of the monofunctional polymerizable compound used in the curable composition for imprints is preferably 100 or more, more preferably 200 or more, and still more preferably 220 or more. In addition, the molecular weight is preferably 1,000 or less, more preferably 800 or less, still more preferably 300 or less, and particularly preferably 270 or less. By setting the lower limit value of the molecular weight to 100 or more, the volatility tends to be suppressed. By setting the upper limit value of the molecular weight to 1,000 or less, the viscosity tends to be reduced.

The boiling point of the monofunctional polymerizable compound used in the curable composition for imprints is preferably 85° C. or higher, more preferably 110° C. or higher, and still more preferably 130° C. or higher. By setting the boiling point at 667 Pa to 85° C. or higher, the volatility can be suppressed. The upper limit value of the boiling point is not particularly defined, but for example, the boiling point at 667 Pa can be set to 200° C. or lower.

The type of the polymerizable group which is contained in the monofunctional polymerizable compound used in the curable composition for imprints is not specifically defined, and examples thereof include an ethylenically unsaturated group and an epoxy group, among which an ethylenically unsaturated group is preferable. Examples of the ethylenically unsaturated group include a (meth)acryloyl group and a vinyl group, among which a (meth)acryloyl group is more preferable, and an acryloyl group is still more preferable. The (meth)acryloyl group is preferably a (meth)acryloyloxy group.

The type of atoms constituting the monofunctional polymerizable compound used in the curable composition for imprints is not particularly defined, but the monofunctional polymerizable compound is preferably constituted of only atoms selected from a carbon atom, an oxygen atom, a hydrogen atom, and a halogen atom, and is more preferably constituted of only atoms selected from a carbon atom, an oxygen atom, and a hydrogen atom.

A preferred first embodiment of the monofunctional polymerizable compound used in the curable composition for imprints is a compound having a linear or branched hydrocarbon chain having 4 or more carbon atoms.

The hydrocarbon chain in the present invention represents an alkyl chain, an alkenyl chain, or an alkynyl chain, preferably an alkyl chain or alkenyl chain, and more preferably an alkyl chain.

In the present invention, the alkyl chain represents an alkyl group and an alkylene group. Similarly, the alkenyl chain represents an alkenyl group and an alkenylene group, and the alkynyl chain represents an alkynyl group and an alkynylene group. Among these, a linear or branched alkyl group or alkenyl group is more preferable, a linear or branched alkyl group is still more preferable, and a linear alkyl group is even still more preferable.

The linear or branched hydrocarbon chain (preferably an alkyl group) has 4 or more carbon atoms, preferably 6 or more carbon atoms, more preferably 8 or more carbon atoms, still more preferably 10 or more carbon atoms, and particularly preferably 12 or more carbon atoms. The upper limit value of the number of carbon atoms is not particularly defined, but can be, for example, 25 or less.

The linear or branched hydrocarbon chain may contain an ether group (—O—), but it is preferable not to contain an ether group from the viewpoint of improving releasability.

By using a monofunctional polymerizable compound having such a hydrocarbon chain, a relatively small addition amount thereof results in reduced modulus of elasticity of the cured product (pattern), thereby improving the releasability. In addition, in a case where a monofunctional polymerizable compound having a linear or branched alkyl group is used, the interfacial energy between the mold and the cured product (pattern) can be reduced, and therefore the releasability can be further improved.

Preferred hydrocarbon groups which are contained in the monofunctional polymerizable compound used in the curable composition for imprints include the following (1) to (3).

(1) a linear alkyl group having 8 or more carbon atoms

(2) a branched alkyl group having 10 or more carbon atoms

(3) an alicyclic or aromatic ring substituted with a linear or branched alkyl group having 5 or more carbon atoms

(1) Linear Alkyl Group Having 8 or More Carbon Atoms

The linear alkyl group having 8 or more carbon atoms is more preferably one having 10 or more carbon atoms, still more preferably 11 or more carbon atoms, and particularly preferably 12 or more carbon atoms. In addition, the number of carbon atoms in the linear alkyl group having 8 or more carbon atoms is preferably 20 or less, more preferably 18 or less, still more preferably 16 or less, and particularly preferably 14 or less.

(2) Branched Alkyl Group Having 10 or More Carbon Atoms

The branched alkyl group having 10 or more carbon atoms is preferably one having 10 to 20 carbon atoms, more preferably 10 to 16 carbon atoms, still more preferably 10 to 14 carbon atoms, and particularly preferably 10 to 12 carbon atoms.

(3) Alicyclic or Aromatic Ring Substituted with Linear or Branched Alkyl Group Having 5 or More Carbon Atoms

The linear or branched alkyl group having 5 or more carbon atoms is more preferably a linear alkylene group. The number of carbon atoms in the alkyl group is more preferably 6 or more, still more preferably 7 or more, and particularly preferably 8 or more. The number of carbon atoms in the alkyl group is preferably 14 or less, more preferably 12 or less, and still more preferably 10 or less.

The ring of the alicyclic or aromatic ring may be a monocyclic ring or a fused ring, but is preferably a monocyclic ring. In a case of a fused ring, the number of rings is preferably 2 or 3. The ring is preferably a 3- to 8-membered ring, more preferably a 5- or 6-membered ring, and still more preferably a 6-membered ring. In addition, the ring is an alicyclic ring or an aromatic ring, but is preferably an aromatic ring. Specific examples of the ring include a cyclohexane ring, a norbornane ring, an isobornane ring, a tricyclodecane ring, a tetracyclododecane ring, an adamantane ring, a benzene ring, a naphthalene ring, an anthracene ring, and a fluorene ring. Among these, a cyclohexane ring, a tricyclodecane ring, an adamantane ring, and a benzene ring are more preferable, and a benzene ring is still more preferable.

The monofunctional polymerizable compound used in the curable composition for imprints is preferably a compound in which a linear or branched hydrocarbon chain having 4 or more carbon atoms and a polymerizable group are bonded to each other directly or through a linking group; and more preferably a compound in which any one of the above groups (1) to (3) and a polymerizable group are directly bonded to each other. Examples of the linking group include —O—, —C(═O)—, —CH₂—, and a combination thereof. The monofunctional polymerizable compound used in the present invention is particularly preferably a linear alkyl(meth)acrylate in which a linear alkyl group having 8 or more carbon atoms (1) and a (meth)acryloyloxy group are directly bonded to each other.

Examples of the monofunctional polymerizable compound of the first embodiment include the following first group and second group. However, it goes without saying that the present invention is not limited to these groups. In addition, the first group is more preferable than the second group.

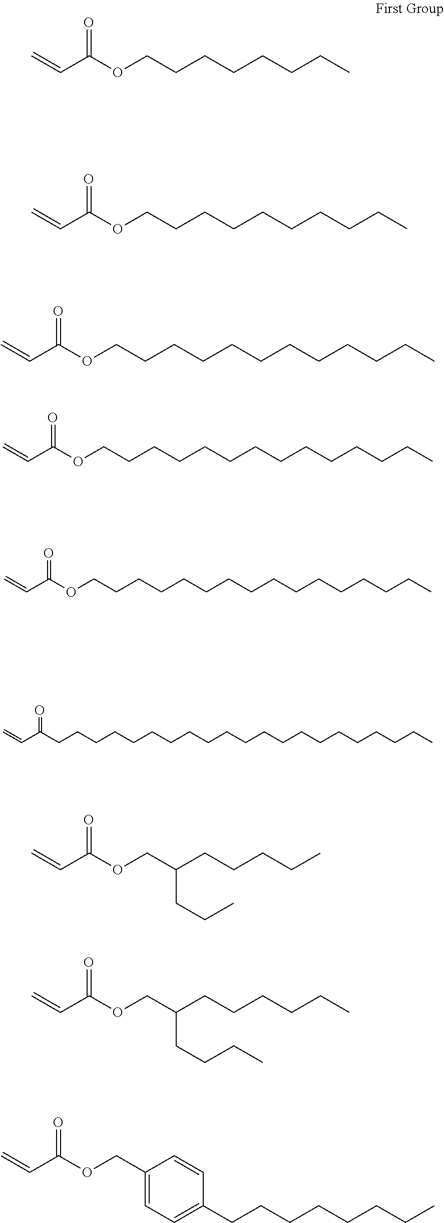

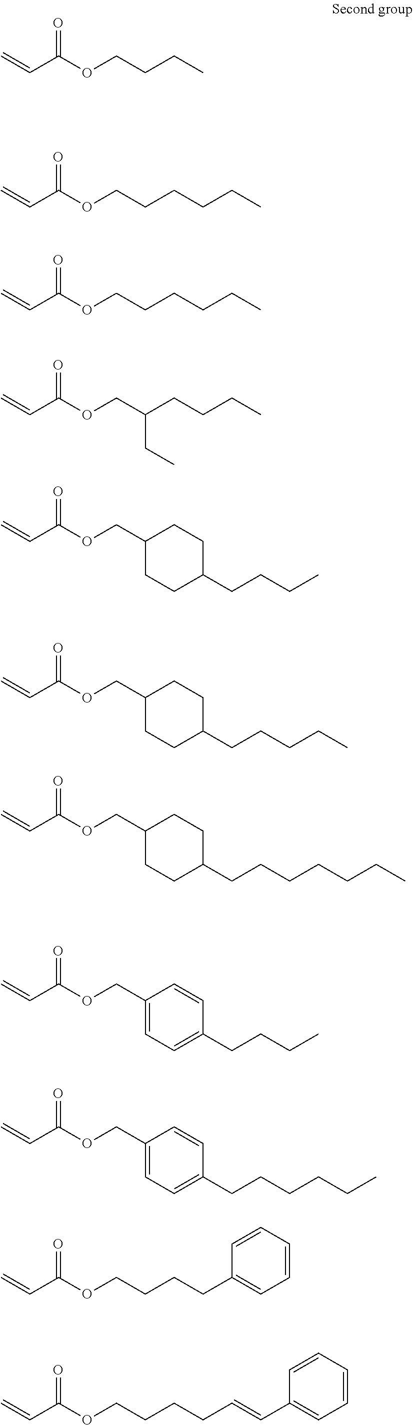

A preferred second embodiment of the monofunctional polymerizable compound used in the curable composition for imprints is a compound having a cyclic structure. The cyclic structure is preferably a 3- to 8-membered monocyclic ring or fused ring. The number of rings constituting the fused ring is preferably 2 or 3. The cyclic structure is more preferably a 5-membered ring or a 6-membered ring, and still more preferably a 6-membered ring. In addition, a monocyclic ring is more preferable.

The number of cyclic structures in one molecule of the polymerizable compound may be one or two or more, but is preferably one or two and more preferably one. In a case of a fused ring, the fused ring is considered as one cyclic structure.

Examples of the monofunctional polymerizable compound according to the second embodiment include the following compounds. However, it goes without saying that the present invention is not limited to these compounds.

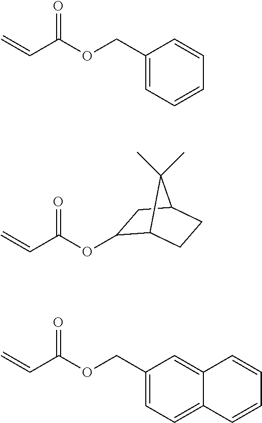 [SMILES: C=CC(=O)OCc1ccccc1 ; C=CC(=O)OC1CC2CCC1C2(C)C ; C=CC(=O)OCc1ccc2ccccc2c1]

In the present invention, monofunctional polymerizable compounds other than the above-mentioned monofunctional polymerizable compounds may be used as long as it does not depart from the spirit of the present invention, and examples thereof include monofunctional polymerizable compounds among the polymerizable compounds described in JP2014-170949A, the contents of which are incorporated herein.

The content of the monofunctional polymerizable compound used in the curable composition for imprints with respect to the total polymerizable compound in the curable composition for imprints is preferably 6% by mass or more, more preferably 8% by mass or more, still more preferably 10% by mass or more, and particularly preferably 12% by mass or more. The content of the monofunctional polymerizable compound is more preferably 60% by mass or less, and may be 55% by mass or less.

In the present invention, only one type of monofunctional polymerizable compound may be contained, or two or more types of monofunctional polymerizable compounds may be contained. In a case where two or more types of monofunctional polymerizable compounds are contained, the total amount thereof is preferably within the above range.

On the other hand, the polyfunctional polymerizable compound used in the curable composition for imprints is not particularly defined, but preferably contains at least one of an alicyclic ring or an aromatic ring, and more preferably contains an aromatic ring. In the following description, a compound containing at least one of an alicyclic ring or an aromatic ring may be referred to as a ring-containing polyfunctional polymerizable compound. In the present invention, by using a ring-containing polyfunctional polymerizable compound, it is possible to more effectively suppress etching characteristics, particularly pattern disconnection after etching. This is presumed to be because the etching selectivity with respect to an object to be processed (for example, Si, Al, Cr, or an oxide thereof) at the time of etching is further improved.

The molecular weight of the ring-containing polyfunctional polymerizable compound used in the curable composition for imprints is preferably 1,000 or less, more preferably 800 or less, still more preferably 500 or less, and even still more preferably 350 or less. By setting the upper limit value of the molecular weight to 1,000 or less, the viscosity tends to be reduced.

The lower limit value of the molecular weight is not particularly defined, but can be, for example, 200 or more.

The number of polymerizable groups contained in the ring-containing polyfunctional polymerizable compound used in the curable composition for imprints is 2 or more, preferably 2 to 7, more preferably 2 to 4, still more preferably 2 or 3, and particularly preferably 2.

The type of polymerizable group contained in the ring-containing polyfunctional polymerizable compound used in the curable composition for imprints is not particularly defined, and examples thereof include an ethylenically unsaturated group and epoxy group, among which an ethylenically unsaturated group is preferable. Examples of the ethylenically unsaturated group include a (meth)acryloyl group and a vinyl group, among which a (meth)acryloyl group is more preferable and an acryloyl group is still more preferable. In addition, the (meth)acryloyl group is preferably a (meth)acryloyloxy group. Two or more types of polymerizable groups may be contained in one molecule, or two or more polymerizable groups of the same type may be contained in one molecule.

The type of atoms constituting the ring-containing polyfunctional polymerizable compound used in the curable composition for imprints is not particularly defined, but the ring-containing polyfunctional polymerizable compound is preferably constituted of only atoms selected from a carbon atom, an oxygen atom, a hydrogen atom, and a halogen atom, and is more preferably constituted of only atoms selected from a carbon atom, an oxygen atom, and a hydrogen atom.

The ring contained in the ring-containing polyfunctional polymerizable compound used in the curable composition for imprints may be a monocyclic ring or a fused ring, but is preferably a monocyclic ring. In a case of a fused ring, the number of rings is preferably 2 or 3. The ring is preferably a 3- to 8-membered ring, more preferably a 5- or 6-membered ring, and still more preferably a 6-membered ring. In addition, the ring may be an alicyclic ring or an aromatic ring, but is preferably an aromatic ring. Specific examples of the ring include a cyclohexane ring, a norbornane ring, an isobornane ring, a tricyclodecane ring, a tetracyclododecane ring, an adamantane ring, a benzene ring, a naphthalene ring, an anthracene ring, and a fluorene ring. Among these, a cyclohexane ring, a tricyclodecane ring, an adamantane ring, and a benzene ring are more preferable, and a benzene ring is still more preferable.

The number of rings in the ring-containing polyfunctional polymerizable compound used in the curable composition for imprints may be one or two or more, but is preferably one or two and more preferably one. In a case of a fused ring, the fused ring is considered as one ring.

The structure of the ring-containing polyfunctional polymerizable compound used in the curable composition for imprints is preferably represented by (polymerizable group)-(single bond or divalent linking group)-(divalent group having a ring)-(single bond or a divalent linking group)-(polymerizable group). Here, the linking group is more preferably an alkylene group, and still more preferably an alkylene group having 1 to 3 carbon atoms.

The ring-containing polyfunctional polymerizable compound used in the curable composition for imprints is preferably represented by Formula (1-1).

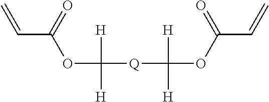

In Formula (1-1), Q represents a divalent group having an alicyclic ring or an aromatic ring.

The preferred range of the alicyclic ring or aromatic ring in Q is the same as described above.

Examples of the polyfunctional polymerizable compound used in the curable composition for imprints include the following first group and second group. However, it goes without saying that the present invention is not limited to these groups. The first group is more preferable.

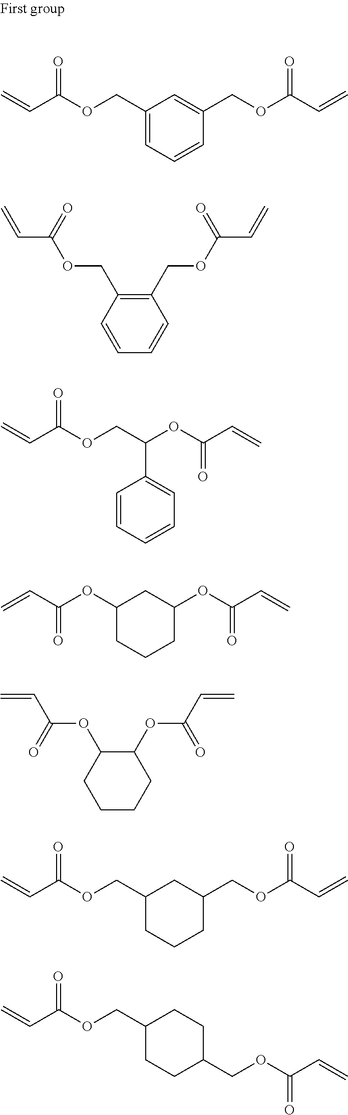

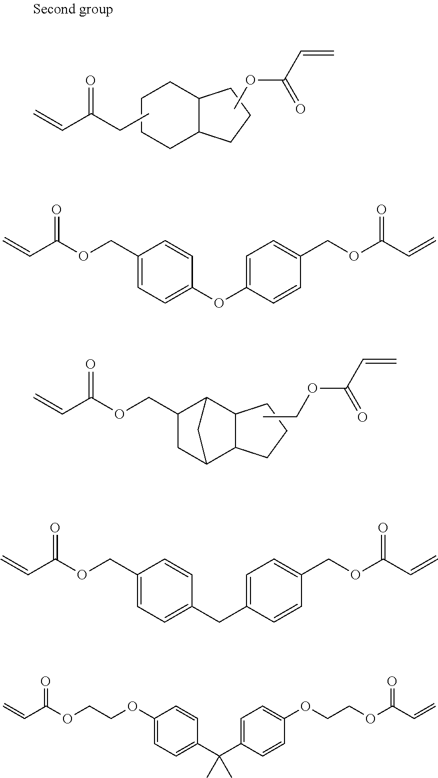

The curable composition for imprints may contain polyfunctional polymerizable compounds other than the ring-containing polyfunctional polymerizable compound.

Examples of other polyfunctional polymerizable compounds used in the curable composition for imprints include polyfunctional polymerizable compounds having no ring among the polymerizable compounds described in JP2014-170949A, the contents of which are incorporated herein. More specifically, for example, the following compounds are exemplified.

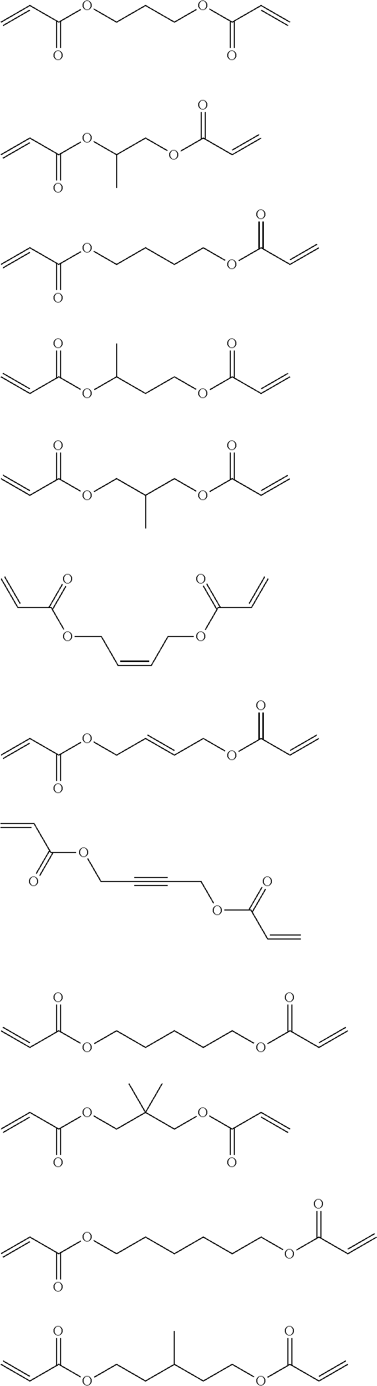

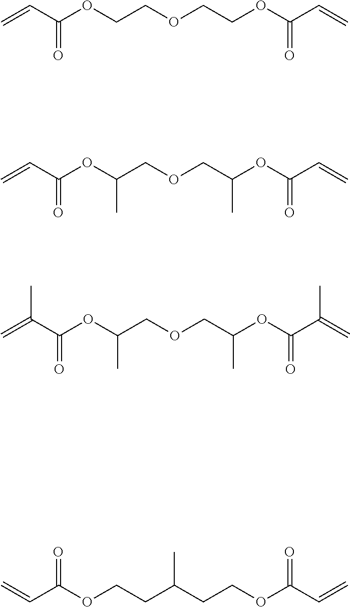

The content of the polyfunctional polymerizable compound is preferably 30% by mass or more, more preferably 45% by mass or more, still more preferably 50% by mass or more, and even still more preferably 55% by mass or more, and may be 60% by mass or more, and may be 70% by mass or more, with respect to the total polymerizable compound in the curable composition for imprints. In addition, the upper limit value of the content of the polyfunctional polymerizable compound is preferably less than 95% by mass and more preferably 90% by mass or less, and it can also be 85% by mass or less. In particular, in a case where the content of the ring-containing polyfunctional polymerizable compound is set to 30% by mass or more of the total polymerizable compound, the etching selectivity with respect to an object to be processed (for example, Si, Al, Cr, or an oxide thereof) at the time of etching is further improved and therefore the disconnection of the pattern after etching can be suppressed.

The curable composition for imprints may contain only one type of polyfunctional polymerizable compound or may contain two or more types of polyfunctional polymerizable compounds. In a case where two or more types of polyfunctional polymerizable compounds are contained, the total amount thereof is preferably within the above range.

In the curable composition for imprints used in the present invention, preferably 85% by mass or more, more preferably 90% by mass or more, and still more preferably 93% by mass or more of the composition is a polymerizable compound.

<<Other Components>>

The curable composition for imprints may contain additives other than the polymerizable compound. Other additives may include a photopolymerization initiator, a surfactant, a sensitizer, a mold release agent, an antioxidant, a polymerization inhibitor, and the like.

As the photopolymerization initiator, the same photopolymerization initiator as described in the section of <Composition for forming underlayer film for imprints> is preferably used.

In a case of being blended, the content of the photopolymerization initiator used in the curable composition for imprints is, for example, 0.01% to 15% by mass, preferably 0.1% to 12% by mass, and more preferably 0.2% to 7% by mass. In a case where two or more types of photopolymerization initiators are used, the total amount thereof is within the above range.

With respect to the surfactant, sensitizer, mold release agent, antioxidant, and polymerization inhibitor, individual components described in JP2013-036027A, JP2014-090133A, and JP2013-189537A can be used in addition to the components described in the Examples which will be described later. Regarding the content and the like, the description in the above-mentioned patent publications can be referred to.

Specific examples of the curable composition for imprints that can be used in the present invention include compositions described in the Examples which will be described later, and compositions described in JP2013-036027A, JP2014-090133A, and JP2013-189537A, the contents of which are incorporated herein. In addition, the preparation of the curable composition for imprints and the formation method of the film (pattern forming layer) can be referred to the description in the above-mentioned patent publications, the contents of which are incorporated herein.

A conventionally known storage container can be used as a storage container for the curable composition for imprints used in the present invention. In addition, as the storage container, it is also preferable to use a multi-layer bottle in which the inner wall of the container is composed of 6 types and 6 layers of resin, or a bottle having a seven-layer structure of six types of resins, for the purpose of suppressing the incorporation of impurities into raw materials and compositions. Examples of such a container include containers described in JP2015-123351A.

<Relationship Between Composition for Forming Underlayer Film for Imprints and Curable Composition for Imprints>

In the kit according to the embodiment of the present invention, the surface tension (γResist) of the curable composition for imprints, the surface tension (γUL) of the non-volatile component in the composition for forming an underlayer film for imprints, and the ΔHSP satisfy any of the following (1) to (3), but more preferably satisfy (1) from the viewpoint of the homogeneity of the imprinted cured film.

γUL−γResist≥3 and |ΔHSP|≤0.5, (1)

γUL−γResist≥5 and |ΔHSP|≤1.0, (2)

γUL−γResist≥6 and |ΔHSP|≤3.0, (3)

The |ΔHSP| is 3.0 or less, preferably 2.0 or less, more preferably 1.0 or less, and still more preferably 0.5 or less. By setting the ΔHSP to 3.0 or less, the spreadability of the curable composition for imprints on the underlayer film is improved, and therefore a uniform residual film can be secured. Furthermore, the solubility of the curable composition for imprints and the non-volatile component in the composition for forming an underlayer film for imprints is improved, and therefore the homogeneity of the residual film is also improved.

The Δγ (that is, γUL-γResist) is preferably 3 mN/m or more, more preferably 5 mN/m or more, and still more preferably 6 mN/m or more, and may be 7 mN/m or more. The upper limit of the Δγ is not particularly defined, but can be, for example, 10 mN/m or less, and may be 9 mN/m or less.

By adopting such a configuration, the wettability of the curable composition for imprints formed on the underlayer film can be improved, and also the residual film uniformity can be improved.

In the kit according to the embodiment of the present invention, the difference between the Ohnishi parameter of the non-volatile component in the composition for forming an underlayer film for imprints and the Ohnishi parameter of the curable composition for imprints is preferably less than 1.0, more preferably 0.5 or less, and still more preferably less than 0.4. The lower limit value of the difference between the Ohnishi parameters is ideally 0, but even in a case where it is 0.05 or more, such a value is a practical level. By making the difference between the Ohnishi parameters less than 1.0, particularly 0.5 or less, it is possible to further improve the processing resistance.

In the kit according to the embodiment of the present invention, an aspect is exemplified in which the component having the highest content in the non-volatile components in the composition for forming an underlayer film for imprints and the component having the highest content in the curable composition for imprints are the same component. By adopting such a configuration, the compatibility of the underlayer film and the imprint layer tends to be further improved.

In the kit according to the embodiment of the present invention, an aspect is exemplified in which 50% by mass or more of the non-volatile component in the composition for forming an underlayer film for imprints and 50% by mass or more of the component contained in the curable composition for imprints are the same compound. By adopting such a configuration, the compatibility of the underlayer film and the imprint layer tends to be further improved.

<Method for Producing Cured Product Pattern>

The method for producing a cured product pattern according to the embodiment of the present invention is a method for producing a cured product pattern using the kit according to the embodiment of the present invention, which includes an underlayer film forming step of applying a composition for forming an underlayer film for imprints onto a substrate to form an underlayer film; an applying step of applying a curable composition for imprints onto a surface of the underlayer film; a mold contact step of bringing the curable composition for imprints into contact with a mold having a pattern for transferring a pattern shape; a light irradiation step of irradiating the curable composition for imprints with light to form a cured product; and a mold release step of separating the cured product from the mold.

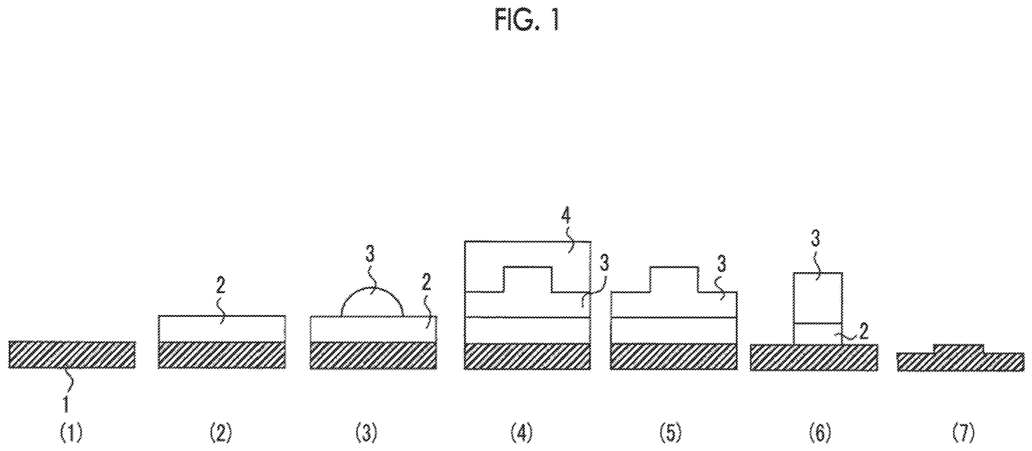

Hereinafter, the method for forming a cured product pattern (the method for producing a cured product pattern) will be described with reference to FIG. 1. Needless to say, the configuration of the present invention is not limited to that shown in FIG. 1.

<<Underlayer Film Forming Step>>

In the underlayer film forming step, an underlayer film 2 is usually formed on a substrate 1 as shown in FIG. 1(2). The underlayer film is preferably formed by applying the composition for forming an underlayer film for imprints in a layered manner onto the substrate. The underlayer film may be formed directly on the surface of the substrate 1, or an adhesion film may be provided on the surface of the substrate 1. In a case where the adhesion film is provided, it is preferable to provide the underlayer film on the surface of the adhesion film. For example, a film formed from the composition for forming an underlayer film for imprints described in JP2014-024322A can be used as the adhesion film.

The application method of the composition for forming an underlayer film for imprints onto a substrate is not particularly defined, and generally well-known application methods can be employed. Specific examples of the application method include a dip coating method, an air knife coating method, a curtain coating method, a wire bar coating method, a gravure coating method, an extrusion coating method, a spin coating method, a slit scanning method, and an ink jet method, among which a spin coating method is preferable.

In addition, after the composition for forming an underlayer film for imprints is applied onto the substrate in a layered manner, the solvent is preferably volatilized (dried) by heat to form an underlayer film which is a thin film. In the present invention, as described above, it is preferable to heat (bake) the composition for forming an underlayer film for imprints applied in a layered manner at 30° C. to 90° C. (preferably 40° C. or higher and 70° C. or lower). The heating time can be 30 seconds to 5 minutes.

The thickness of the underlayer film 2 is preferably 2 nm or more, more preferably 3 nm or more, and still more preferably 4 nm or more, and may be 5 nm or more or may be 7 nm or more. In addition, the thickness of the underlayer film is preferably 20 nm or less, more preferably 15 nm or less, and still more preferably 10 nm or less. By setting the film thickness to 2 nm or more, particularly 3 nm or more, the spreadability (wettability) of the curable composition for imprints on the underlayer film is improved, and therefore a uniform residual film can be formed. By setting the film thickness to 20 nm or less, the residual film after imprinting becomes thin, film thickness unevenness hardly occurs, and therefore the residual film uniformity tends to be improved.

The material of the substrate is not particularly defined, and reference can be made to the description in paragraph [0103] of JP2010-109092A (the publication number of the corresponding US application is US 2011/199592), the contents of which are incorporated herein. In addition to the above-mentioned substrate material, there are, for example, a sapphire substrate, a silicon carbide substrate, a gallium nitride substrate, an aluminum substrate, an amorphous aluminum oxide substrate, a polycrystalline aluminum oxide substrate, and a substrate made of GaAsP, GaP, AlGaAs, InGaN, GaN, AlGaN, ZnSe, AlGa, InP, or ZnO. Specific examples of materials for a glass substrate include aluminosilicate glass, aluminoborosilicate glass, and barium borosilicate glass. In the present invention, a silicon substrate is preferable.

<<Applying Step>>

In the applying step, for example, as shown in FIG. 1 (3), a curable composition 3 for imprints is applied onto the surface of the underlayer film 2.

The method of applying the curable composition for imprints is not particularly defined, and reference can be made to the description in paragraph [0102] of JP2010-109092A (the publication number of the corresponding US application is US 2011/199592), the contents of which are incorporated herein. The curable composition for imprints is preferably applied onto the surface of the underlayer film by an ink jet method. The application is preferably carried out by an ink jet method. In addition, the curable composition for imprints may be applied by multiple applications. In the method of disposing liquid droplets on the surface of the underlayer film by an ink jet method or the like, the amount of the liquid droplets is preferably about 1 to 20 pL, and it is preferable to dispose the liquid droplets on the surface of the underlayer film with an interval between the liquid droplets. The interval between the liquid droplets is preferably 10 to 1000 μm. In a case of the ink jet method, the interval between the liquid droplets is set to the arrangement interval between the ink jet nozzles.

Furthermore, the volume ratio between the underlayer film 2 and the film-like curable composition 3 for imprints applied onto the substrate is preferably 1:1 to 500, more preferably 1:10 to 300, and still more preferably 1:50 to 200.

That is, as a laminate formed from the kit according to the embodiment of the present invention, the present invention discloses a laminate having an underlayer film which is formed from the above-mentioned composition for forming an underlayer film for imprints and an imprint layer which is formed from the above-mentioned curable composition for imprints and is positioned on the surface of the underlayer film.

In addition, the method for producing a laminate according to the embodiment of the present invention is a method for producing a laminate using the kit according to the embodiment of the present invention, which includes applying the curable composition for imprints onto the surface of the underlayer film formed from the composition for forming an underlayer film for imprints. Furthermore, the method for producing a laminate according to the embodiment of the present invention preferably includes a step of applying the composition for forming an underlayer film for imprints onto a substrate in a layered manner, and a step of heating (baking) the composition for forming an underlayer film for imprints applied in a layered manner at 30° C. to 90° C. (preferably 40° C. or higher and 70° C. or lower). The heating time can be 30 seconds to 5 minutes.

<<Mold Contact Step>>

In the mold contact step, for example, as shown in FIG. 1 (4), the curable composition 3 for imprints and a mold 4 having a pattern for transferring a pattern shape are brought into contact with each other. Through such a step, a desired cured product pattern (imprint pattern) is obtained.

Specifically, the mold 4 is pressed against the surface of the film-like curable composition 3 for imprints in order to transfer a desired pattern to a film-like curable composition for imprints.

The mold may be a light-transmissive mold or a non-light-transmissive mold. In a case where a light-transmissive mold is used, it is preferable to irradiate the curable composition 3 with light from the mold side. On the other hand, in a case where a non-light-transmissive mold is used, it is preferable to use a light-transmissive substrate as the substrate and irradiate light from the substrate side. In the present invention, it is more preferable to use a light-transmissive mold and irradiate light from the mold side.

The mold that can be used in the present invention is a mold having a pattern to be transferred. Although the pattern on the mold may be formed according to the desired processing accuracy, for example, by photolithography, electron beam lithography, or the like, the method for producing a mold pattern is not particularly limited in the present invention. In addition, the pattern formed by the method for producing a cured product pattern according to the embodiment of the present invention can also be used as a mold.

The material constituting the light-transmissive mold used in the present invention is not particularly limited, and examples thereof include glass, quartz, polymethyl methacrylate (PMMA), a light-transmissive resin such as polycarbonate resin, a transparent metal vapor-deposited film, a flexible film such as polydimethylsiloxane, a photo-cured film, and a metal film, among which quartz is preferable.

In the present invention, the material for the non-light-transmissive mold to be used in a case where a light-transmissive substrate is used is not particularly limited and may be any one having a predetermined strength. Specific examples of the non-light-transmissive mold material include, but are not particularly limited to, a ceramic material, a vapor-deposited film, a magnetic film, a reflective film, a metal substrate such as Ni, Cu, Cr, or Fe, and a substrate such as SiC, silicon, silicon nitride, polysilicon, silicon oxide, or amorphous silicon.

In the above-mentioned method for producing a cured product pattern, the mold pressure is preferably 10 atm or lower in a case where imprint lithography is carried out using the curable composition for imprints. By setting the mold pressure to 10 atm or lower, the mold and the substrate are hardly deformed and therefore the patterning accuracy tends to be improved. In addition, it is also preferable from the viewpoint that there is a tendency that the apparatus may be small-sized because the pressure to be given to the mold is low. The mold pressure is preferably selected from a range in which uniformity of mold transfer can be ensured while the residual film of the curable composition for imprints corresponding to the mold convex portion is reduced.

In addition, it is also preferable that the curable composition for imprints and the mold are brought into contact with each other in an atmosphere containing helium gas or condensable gas, or both helium gas and condensable gas.

<<Light Irradiation Step>>

In the light irradiation step, the curable composition for imprints is irradiated with light to form a cured product. The irradiation amount of light irradiation in the light irradiation step may be sufficiently larger than the minimum irradiation amount necessary for curing. The irradiation amount necessary for curing is appropriately determined by examining the consumption of unsaturated bonds in the curable composition for imprints.

The type of light to irradiate is not particularly defined, and may be, for example, ultraviolet light.

In the imprint lithography applied to the present invention, light irradiation is carried out while keeping the substrate temperature generally at room temperature, where the light irradiation may alternatively be carried out under heating for the purpose of enhancing the reactivity. Light irradiation can also be carried out in vacuo, since a vacuum conditioning prior to the light irradiation is effective for preventing entrainment of air bubbles, for suppressing the reactivity from being reduced due to incorporation of oxygen, and for improving the adhesiveness between the mold and the curable composition for imprints. In the method for producing a cured product pattern, the degree of vacuum at the time of light irradiation is preferably in the range from 10⁻¹ Pa to normal pressure.

Upon exposure, the exposure illuminance is preferably in the range of 1 mW/cm² to 500 mW/cm².

In the method for producing a cured product pattern, after curing the film-like curable composition for imprints (pattern forming layer) by light irradiation, a step of applying heat to the cured pattern to cure the pattern may be further included, if necessary. The temperature for heat-curing the curable composition for imprints after light irradiation is preferably 150° C. to 280° C. and more preferably 200° C. to 250° C. The time for applying heat is preferably 5 to 60 minutes and more preferably 15 to 45 minutes.

<<Mold Release Step>>

In the mold release step, the cured product and the mold are separated from each other (FIG. 1 (5)). The obtained cured product pattern can be used for various applications as described later.

That is, the present invention discloses a laminate further having a cured product pattern formed from the curable composition for imprints on the surface of the underlayer film. In addition, the film thickness of the pattern forming layer made of the curable composition for imprints used in the present invention is about 0.01 μm to 30 μm, although it varies depending on the intended use.

Further, as will be described later, etching or the like can be carried out.

<Cured Product Pattern and Applications Thereof>

As described above, the cured product pattern formed by the method for producing a cured product pattern can be used as a permanent film used for a liquid crystal display (LCD) device or the like, or as an etching resist (lithography mask) for producing a semiconductor element.

In particular, the present invention discloses a method for producing a circuit board which includes a step of obtaining a cured product pattern by the method for producing a cured product pattern according to the embodiment of the present invention. The method for producing a circuit board according to the embodiment of the present invention may further include a step of etching or ion implantation on a substrate using the cured product pattern obtained by the above-mentioned method for producing a cured product pattern as a mask, and a step of forming an electronic member. The circuit board is preferably a semiconductor element. The present invention discloses a method for producing an electronic device which further includes a step of obtaining a circuit board by the above-mentioned method for producing a circuit board, and a step of connecting the circuit board and a control mechanism for controlling the circuit board.

In addition, in a case where a grid pattern is formed on the glass substrate of the liquid crystal display device using the pattern formed by the above-mentioned method for producing a cured product pattern, it is possible to produce a polarizing plate having a large screen size (for example, 55 inches or more than 60 inches) with low reflection and absorption at low cost. For example, a polarizing plate described in JP2015-132825A and WO2011-132649 can be produced. One inch is 25.4 mm.

The cured product pattern formed in the present invention is also useful as an etching resist (lithography mask) as shown in FIG. 1. In a case where the cured product pattern is used as the etching resist, first, for example, using a silicon substrate (silicon wafer or the like) on which a thin film of SiO₂ or the like is formed as a substrate, for example, a fine cured product pattern of nano or micron order is formed on the substrate by the above-mentioned method for producing a cured product pattern. In the present invention, it is particularly advantageous in that a nano-order fine pattern can be formed, and further a pattern having a size of 50 nm or less, particularly 30 nm or less can be formed. The lower limit value of the size of the cured product pattern formed by the above-mentioned method for producing a cured product pattern is not particularly defined, but can be, for example, 1 nm or more.

In addition, the present invention also discloses a method for producing a mold for imprints which includes a step of obtaining a cured product pattern on a substrate by the method for producing a cured product pattern according to the embodiment of the present invention, and a step of etching on the substrate using the obtained cured product pattern.

By etching using an etching gas such as hydrogen fluoride in a case of wet etching or CF₄ in a case of dry etching, a desired cured product pattern can be formed on the substrate. The cured product pattern has particularly good etching resistance against dry etching. That is, the pattern formed by the above-mentioned method for producing a cured product pattern is preferably used as a lithography mask.

Specifically, the pattern formed in the present invention can be preferably used for the production of a recording medium such as a magnetic disc, a light receiving element such as a solid image pickup element, a light emitting element such as a light emitting diode (LED) or an organic electroluminescence (organic EL), an optical device such as a liquid crystal display (LCD) device, an optical component such as a diffraction grating, a relief hologram, an optical waveguide, an optical filter, or a microlens array, a member for flat panel displays such as a thin film transistor, an organic transistor, a color filter, an antireflection film, a polarizing plate, a polarizing element, an optical film, or a pillar material, a nanobio device, an immunoassay chip, a deoxyribonucleic acid (DNA) separation chip, a microreactor, a photonic liquid crystal, a guide pattern for directed self-assembly (DSA) using self-organization of a block copolymer, or the like.

### Examples

Hereinafter, the present invention will be described in more detail with reference to examples. The materials, amounts used, ratios, processing details, processing procedures, and the like shown in the following examples can be changed as appropriate without departing from the spirit of the present invention. Therefore, the scope of the present invention is not limited to the specific examples shown below.

<Preparation of Non-Volatile Components of Composition for Forming Underlayer Film for Imprints>

As shown in Tables 1 to 4 below, individual compounds (A-1 to B-5) other than solvents (C-1 to C-4) were prepared or blended, and then two-stage filtration was carried out with a polytetrafluoroethylene (PTFE) filter having a pore size of 0.1 μm and a PTFE filter having a pore size of 0.003 μm to obtain non-volatile components.

<Preparation of Composition for Forming Underlayer Film for Imprints>

As shown in Tables 1 to 4 below, individual compounds (A-1 to C-4) were blended, and then two-stage filtration was carried out with a polytetrafluoroethylene (PTFE) filter having a pore size of 0.1 pun and a PTFE filter having a pore size of 0.003 μm to obtain compositions for forming an underlayer film for imprints in Examples or Comparative Examples.

<Preparation of Curable Compositions (V-1) to (V-7) for Imprints>

As shown in Table 5 below, individual compounds were blended, and further 200 mass ppm (0.02% by mass) of 4-hydroxy-2,2,6,6-tetramethylpiperidine-1-oxyl free radical (manufactured by Tokyo Chemical Industry Co., Ltd.) as a polymerization inhibitor was added with respect to the total amount of polymerizable compounds. This was followed by filtration with a polytetrafluoroethylene (PTFE) filter having a pore size of 0.1 μm and then filtration with a PTFE filter having a pore size of 0.003 μm to obtain curable compositions (V-1) to (V-7) for imprints.

<Measurement of Surface Tension>

The surface tension (γUL) of the non-volatile component in the composition for forming an underlayer film for imprints and the surface tension (γResist) of the curable composition for imprints were measured by a surface tensiometer CBVP-A3 (manufactured by Kyowa Interface Science Co., Ltd.) at 23° C.±0.2° C. using a glass plate. The unit of the surface tension is expressed in mN/m.

<Measurement of Viscosity>

The viscosity was measured by using an E type rotational viscometer RE85L (manufactured by Toki Sangyo Co., Ltd.) equipped with a standard cone rotor (1°34′×R24), and adjusting a sample cup to a temperature of 23° C.±0.2° C. The unit of the viscosity is expressed in mPa·s. In Tables 1 to 4, the viscosity of the non-volatile component means the viscosity of a mixture in a case where two or more non-volatile components are contained.

<Calculation of Distance (ΔHSP) Between Hansen Solubility Parameters>

The Hansen solubility parameter was calculated with HSP calculation software HSPiP.

Individual components (ΔD, ΔP, ΔH) of the Hansen solubility parameter vector were calculated by inputting the structural formula of each compound into the above software in the SMILES format. The distance (ΔHSP) between the Hansen solubility parameters was calculated by applying the calculated Hansen solubility parameter to the following equation.

ΔHSP=(4.0×ΔD²+ΔP²+ΔH²)^{0.5}

For the Hansen solubility parameter vector of the curable composition for imprints and the composition for forming an underlayer film for imprints, the calculated value of the compound with the highest blending amount contained in each composition was adopted (the calculated value of the compound with higher surface tension was adopted in a case where the blending amount is the same.)

<Ohnishi Parameter>

For each of the non-volatile component in the composition for forming an underlayer film for imprints and the curable composition for imprints, the Ohnishi parameter was determined by substituting the numbers of carbon atoms, hydrogen atoms, and oxygen atoms of the constituent components into the following equation. In a case where a plurality of compounds were contained, the weight average value was adopted.

Ohnishi parameter=sum of numbers of carbon, hydrogen and oxygen atoms/(number of carbon atoms−number of oxygen atoms)

<Preparation of Underlayer Film>

A composition for forming an adhesion layer shown in Example 6 of JP2014-24322A was spin-coated on a silicon wafer and heated using a hot plate at 220° C. for 1 minute to form an adhesion film having a thickness of 5 nm. Then, each of the compositions for forming an underlayer film for imprints shown in Tables 1 to 4 was spin-coated on the surface of the adhesion film, and heated using a hot plate under the baking conditions (temperature, time) shown in Tables 1 to 4 to form each of underlayer films having a thickness shown in Tables 1 to 4.

<Film Thickness Stability Ofunderlayer Film>

The film thickness of the underlayer film immediately after the production thereof was measured. Further, the wafer on which the underlayer film was formed was left at room temperature for 48 hours, and the film thickness of the underlayer film was measured again. The film thickness difference (ΔFT) between the film thickness immediately after the formation of the underlayer film and the film thickness after 48 hours was confirmed.

The film thickness of the underlayer film was measured with an ellipsometer.

A: ΔFT≤0.5 nm

B: 0.5 nm<ΔFT≤1.0 nm

C: ΔFT>1.0 nm

D: Other than the above A to C (for example, the film could not be formed, or the film state was not maintained after 48 hours.)

<Evaluation of Wettability of IJ Liquid Droplets>

On the surface of each of the underlayer films obtained in the section of <Preparation of underlayer film>, the curable composition for imprints, which was one of the curable compositions V-1 to V-7 for imprints shown in Table 5 and of which the temperature was adjusted to 23° C., was ejected at a liquid droplet volume of 6 pL per nozzle using an ink jet printer DMP-2831 (manufactured by FUJIFILM Dimatics Inc.), so that the liquid droplets were applied in a square array at intervals of about 880 μm on the surface of the underlayer film. After the application, the shape of the liquid droplets 3 seconds later was imaged, and the average diameter of the ink jet (IJ) liquid droplets was measured.

A: average diameter of U liquid droplets >400 μm

B: 320 μm<average diameter of IJ liquid droplets <400 μm

C: 250 μm <average diameter of IJ liquid droplets <320 μm

D: average diameter of IJ liquid droplets ≤250 μm

<Evaluation of Residual Film Uniformity>

On the surface of each of the underlayer films obtained in the section of <Preparation of underlayer film>, any one of the curable compositions V-1 to V-7 for imprints, shown in Table 5 and adjusted to a temperature of 23° C., was ejected at a liquid droplet volume of 6 pL per nozzle using an ink jet printer DMP-2831 (manufactured by FUJIFILM Dimatics Inc.), so that the liquid droplets were applied in a square array at intervals of about 100 μm on the underlayer film to form a pattern forming layer. Next, a quartz mold (line pattern having a line width of 20 nm and a depth of 50 nm) was pressed against the pattern forming layer in a He atmosphere (replacement rate of 90% or more), and the curable composition for imprints was filled in the concave portion of the mold. In a case where 10 seconds have passed after imprinting, exposure was carried out at 300 mJ/cm² using a high-pressure mercury lamp from the mold side, and then the mold was separated to transfer the pattern to the pattern forming layer to obtain a cured product pattern.

A part of the cured product pattern created by the above method was scraped with a marking bar, and the step at the boundary was measured with an atomic force microscope (AFM) to measure the residual film of the cured product pattern (thickness of the film formed between the concave portion and the substrate). The residual film was measured at 30 points per sample, and the film thickness uniformity (3σ) of the cured product pattern was evaluated.

A: 3σ≤1.5 nm

B: 1.5 nm<3σ≤3.0 nm

C: 3.0 nm<3σ≤5.0 nm

D: 3σ>5.0 nm

<Evaluation of Processing Resistance>

The curable composition for imprints adjusted to a temperature of 23° C. was applied onto the surface of each of the underlayer films obtained in the section of <Preparation of underlayer film> using an ink jet printer DMP-2831 (manufactured by FUJIFILM Dimatics Inc.). The volume of liquid droplets per nozzle was 6 pL, and the liquid droplets were arranged in a square array at intervals of about 100 μm. Next, the sample was pressed against a quartz substrate (without a pattern) in a helium atmosphere (replacement rate of 90% by volume or more). In a case where 10 seconds have passed after imprinting, exposure was carried out at 300 mJ/cm² using a high-pressure mercury lamp from the quartz substrate side, and then the quartz substrate was separated to obtain a thin film (film thickness of about 300 nm) of curable composition for imprints.

The sample was introduced into an etching apparatus (Centura-DPS, manufactured by Applied Materials, Inc.) and etched under the following conditions.

Etching Conditions:

Gas pressure: 10 mTorr (1 Torr is 133.322 Pa.)

Gas type (flow rate): O₂ (10 sccm) (1 sccm=1.69×10⁻⁴ Pa·m³/sec)

Source voltage (W): 50 W

Bias voltage (W): 100 W

Etching time: 20 sec

The surface state of the thin film after etching was observed with a non-contact interference microscope.

A: There was no film thickness unevenness and the entire surface was etched uniformly.

B: Film thickness unevenness occurred in some regions.

C: Film thickness unevenness occurred over the entire surface.

TABLE 1

| | Viscosity | Boiling | Example | Example | Example | Example | Example | Example |
|---|---|---|---|---|---|---|---|---|
| | at 23° C. | point | 1 | 2 | 3 | 4 | 5 | 6 |
| A-1 | 10 | 330 | 0.3 | 0.3 | 0.3 | | | |
| A-2 | 110 | 410 | | | | 0.2 | | |
| A-3 | 63 | 440 | | | | | | 0.25 |
| A-4 | 46 | 400 | | | | | | |
| A-5 | 15 | 320 | | | | | | |
| A-6 | 1050 | 530 | | | | | | |
| A-7 | 22 | 330 | | | | | | |
| A-8 | 20 | 360 | | | | | | |
| A-9 | 5 | 250 | | | | | | |
| A-10 | 6 | 290 | | | | | | |
| A-11 | 10 | 330 | | | | | | |
| A-12 | 1450 | 400 | | | | | | |
| A-13 | Solid | 610 | | | | | | |
| A-14 | 148 | 350 | | | | | 0.2 | |
| B-1 | 120 | — | | | | | | |
| B-2 | 111 | — | | | | | | |
| B-3 | Solid | — | | | | | | |
| B-4 | 12 | — | | | | | | |
| B-5 | 8 | 200 | | | | | | |
| C-1 | | 121 | 99.7 | | 89.7 | 99.8 | 99.8 | 99.75 |
| C-2 | | 126 | | 99.7 | | | | |
| C-3 | | 146 | | | 10 | | | |
| C-4 | | 156 | | | | | | |
| Baking conditions | | | 60° C. min | 60° C./ | 60° C./ | 60° C./ | 60° C./ | 60° C./ |
| | | | | 1 min | 1 min | 1 min | 1 min | 1 min |
| Underlayer | Component d | | 18.1 | 18.1 | 18.1 | 18.6 | 18.4 | 19.1 |
| film | Component p | | 4.5 | 4.5 | 4.5 | 5.1 | 4.8 | 5.7 |
| (non-volatile | Component h | | 5.9 | 5.9 | 5.9 | 5.6 | 5.4 | 6.2 |
| component) | γUL | | 40.3 | 40.3 | 40.3 | 42.1 | 43.2 | 42.2 |
| | Viscosity of | | 10 | 10 | 10 | 110 | 148 | 63 |
| | non-volatile component | | | | | | | |
| | Ohnishi parameter | | 3.2 | 3.2 | 3.2 | 2.9 | 3.0 | 2.9 |
| Imprint | Type | | V-1 | V-1 | V-1 | V-3 | V-5 | V-3 |
| curable | γResist | | 33.0 | 33.0 | 33.0 | 35.0 | 38.0 | 35.0 |
| composition | Component d | | 18.1 | 18.1 | 18.1 | 18.1 | 18.1 | 18.1 |
| | Component p | | 4.5 | 4.5 | 4.5 | 4.5 | 4.5 | 4.5 |
| | Component h | | 5.9 | 5,9 | 5.9 | 5.9 | 5.9 | 5.9 |
| | Ohnishi parameter | | 3.5 | 3.5 | 3.5 | 3.0 | 3.2 | 3.0 |
| Kit | ΔHSP | | 0.00 | 0.00 | 0.00 | 1.20 | 0.84 | 2.35 |
| | Δγ (γUL − γResist) | | 7.3 | 7.3 | 7.3 | 7.1 | 5.2 | 7.2 |
| | Difference between | | 0.3 | 0.3 | 0.3 | 0.1 | 0.2 | 0.1 |
| | Ohnishi parameters | | | | | | | |
| Film thickness of underlayer film | | | 8 | 8 | 8 | 8 | 8 | 8 |
| (nm) | | | | | | | | |
| Film thickness stability of underlayer | | | A | A | A | A | A | A |
| film | | | | | | | | |
| Wettability of IJ liquid droplets | | | A | A | A | A | A | A |
| Residual film uniformity | | | A | A | A | A | A | A |
| Processing resistance | | | A | A | A | A | A | A |
| | | Viscosity | Boiling | Example | Example | Example | Example | Example |
| | | at 23° C. | point | 7 | 8 | 9 | 10 | 11 |
| | A-1 | 10 | 330 | 0.15 | 0.29 | 0.29 | 0.27 | |
| | A-2 | 110 | 410 | | | | | |
| | A-3 | 63 | 440 | | | | | |
| | A-4 | 46 | 400 | 0.1 | | | | |
| | A-5 | 15 | 320 | | | | | |
| | A-6 | 1050 | 530 | | | | | |
| | A-7 | 22 | 330 | | | | | 0.3 |
| | A-8 | 20 | 360 | | | | | |
| | A-9 | 5 | 250 | | | | | |
| | A-10 | 6 | 290 | | | | | |
| | A-11 | 10 | 330 | | | | | |
| | A-12 | 1450 | 400 | | | | | |
| | A-13 | Solid | 610 | | | | | |
| | A-14 | 148 | 350 | | | | | |
| | B-1 | 120 | — | | 0.01 | | | |
| | B-2 | 111 | — | | | | | |
| | B-3 | Solid | — | | | 0.01 | | |
| | B-4 | 12 | — | | | | 0.03 | |
| | B-5 | 8 | 200 | | | | | |
| | C-1 | | 121 | 99.75 | 99.7 | 99.7 | 99.7 | 99.7 |
| | C-2 | | 126 | | | | | |
| | C-3 | | 146 | | | | | |
| | C-4 | | 156 | | | | | |

| Baking conditions | | 60° C./ | 60° C./ | 60° C./ | 60° C./ | 60° C./ |
|---|---|---|---|---|---|---|
| | | 1 min | 1 min | 1 min | 1 min | 1 min |
| Underlayer | Component d | 18.1 | 18.1 | 18.1 | 18.1 | 17 |
| film | Component p | 4.65 | 4.5 | 4.5 | 4.5 | 5.3 |
| (non-volatile | Component h | 6.2 | 5.9 | 5.9 | 5.9 | 6.2 |
| component) | γUL | 40.3 | 40.3 | 40.3 | 40.3 | 41.2 |
| | Viscosity of | 26 | 10 | 10 | 10 | 22 |
| | non-volatile component | | | | | |
| | Ohnishi parameter | 3.3 | 3.2 | 3.2 | 3.2 | 4.0 |
| Imprint | Type | V-1 | V-1 | V-2 | V-2 | V-1 |
| curable | γResist | 33.0 | 33.0 | 34.0 | 34.0 | 33.0 |
| composition | Component d | 18.1 | 18.1 | 18.1 | 18.1 | 18.1 |
| | Component p | 4.5 | 4.5 | 4.5 | 4.5 | 4.5 |
| | Component h | 5.9 | 5.9 | 5.9 | 5.9 | 5.9 |
| | Ohnishi parameter | 3.5 | 3.5 | 3.5 | 3.5 | 3.5 |
| Kit | ΔHSP | 0.34 | 0.00 | 0.00 | 0.00 | 2.36 |
| | Δγ (γUL − γResist) | 7.3 | 7.3 | 6.3 | 6.3 | 8.2 |
| | Difference between | 0.2 | 0.3 | 0.3 | 0.3 | 0.5 |
| | Ohnishi parameters | | | | | |

| | | | | | |
|---|---|---|---|---|---|
| Film thickness of underlayer film | 8 | 8 | 8 | 8 | 8 |
| (nm) | | | | | |
| Film thickness stability of underlayer | A | A | A | A | A |
| film | | | | | |
| Wettability of IJ liquid droplets | A | A | A | A | A |
| Residual film uniformity | A | A | A | A | A |
| Processing resistance | A | A | A | A | A |

TABLE 2

| | Viscosity at | Boiling | Example | Example | Example | Example | Example |
|---|---|---|---|---|---|---|---|
| | 23° C. | point | 12 | 13 | 14 | 15 | 16 |
| A-1 | 10 | 330 | | 0.5 | 0.5 | | 0.1 |
| A-2 | 110 | 410 | | | | 0.3 | |
| A-3 | 63 | 440 | | | | | |
| A-4 | 46 | 400 | | | | | |
| A-5 | 15 | 320 | 0.4 | | | | |
| A-6 | 1050 | 530 | | | | | |
| A-7 | 22 | 330 | | | | | |
| A-8 | 20 | 360 | | | | | |
| A-9 | 5 | 250 | | | | | |
| A-10 | 6 | 290 | | | | | |
| A-11 | 10 | 330 | | | | | |
| A-12 | 1450 | 400 | | | | | |
| A-13 | Solid | 610 | | | | | |
| A-14 | 148 | 350 | | | | | |
| B-1 | 120 | — | | | | | |
| B-2 | 111 | — | | | | | |
| B-3 | Solid | — | | | | | |
| B-4 | 12 | — | | | | | |
| B-5 | 8 | 200 | | | | | |
| C-1 | | 121 | 99.6 | | 30 | 99.7 | 99.9 |
| C-2 | | 126 | | | | | |
| C-3 | | 146 | | 99.5 | | | |
| C-4 | | 156 | | | 69.5 | | |
| Baking conditions | | | 60° C./ | 60° C./ | 60° C./ | 60° C./ | 60° C./ |
| | | | 1 min | 1 min | 1 min | 1 min | 1 min |
| Underlayer | Component d | | 18 | 18.1 | 18 | 18.6 | 18.1 |
| film | Component p | | 4.7 | 4.5 | 4.7 | 5.1 | 4.5 |
| (non-volatile | Component h | | 6.1 | 5.9 | 6.1 | 5.6 | 5.9 |
| component) | γUL | | 38.2 | 40.3 | 38.1 | 42.1 | 40.3 |
| | Viscosity of non-volatile | | 15 | 10 | 10 | 10 | 10 |
| | component | | | | | | |
| | Ohnishi parameter | | 3.2 | 3.2 | 3.2 | 2.9 | 3.2 |
| Imprint curable | Type | | V-2 | V-1 | V-2 | V-2 | V-1 |
| composition | γResist | | 34.0 | 33.0 | 34.0 | 34.0 | 33.0 |
| | Component d | | 18.1 | 18.1 | 18.1 | 18.1 | 18.1 |
| | Component p | | 4.5 | 4.5 | 4.5 | 4.5 | 4.5 |
| | Component h | | 5.9 | 5.9 | 5.9 | 5.9 | 5.9 |
| | Ohnishi parameter | | 3.5 | 3.5 | 3.5 | 3.5 | 3.5 |
| Kit | ΔHSP | | 0.35 | 0.00 | 0.35 | 1.20 | 0.00 |
| | Δγ (γUL − γResist) | | 4.2 | 7.3 | 4.1 | 8.1 | 73 |
| | Difference between | | 0.3 | 0.3 | 0.3 | 0.6 | 0.3 |
| | Ohnishi parameters | | | | | | |
| Film thickness of underlayer film (nm) | | | 8 | 8 | 8 | 8 | 2 |
| Film thickness stability of underlayer | | | B | B | B | A | A |
| film | | | | | | | |
| Wettability of IJ liquid droplets | | | B | A | A | A | B |
| Residual film uniformity | | | B | B | B | A | B |
| Processing resistance | | | A | A | A | B | B |
| | | | | | | Comparative | Comparative |
| | Viscosity at | Boiling | Example | Example | Example | Example | Example |
| | 23° C. | point | 17 | 18 | 19 | 1 | 2 |
| A-1 | 10 | 330 | 0.7 | 0.3 | 0.3 | | |
| A-2 | 110 | 410 | | | | | |
| A-3 | 63 | 440 | | | | | |
| A-4 | 46 | 400 | | | | | |
| A-5 | 15 | 320 | | | | | |
| A-6 | 1050 | 530 | | | | | |
| A-7 | 22 | 330 | | | | | |
| A-8 | 20 | 360 | | | | 0.3 | |
| A-9 | 5 | 250 | | | | | 0.3 |
| A-10 | 6 | 290 | | | | | |
| A-11 | 10 | 330 | | | | | |
| A-12 | 1450 | 400 | | | | | |
| A-13 | Solid | 610 | | | | | |
| A-14 | 148 | 350 | | | | | |
| B-1 | 120 | — | | | | | |
| B-2 | 111 | — | | | | | |
| B-3 | Solid | — | | | | | |
| B-4 | 12 | — | | | | | |
| B-5 | 8 | 200 | | | | | |
| C-1 | — | 121 | 99.3 | 99.7 | 99.7 | 99.7 | 99.7 |
| C-2 | — | 126 | | | | | |
| C-3 | — | 146 | | | | | |
| C-4 | — | 156 | | | | | |

| Baking conditions | | 60° C./ | 30° C./ | 80° C./ | 60° C./ | 60° C./ |
|---|---|---|---|---|---|---|
| | | 1 min | 1 min | 1 min | 1 min | 1 min |
| Underlayer | Component d | 18.1 | 18.1 | 18.1 | 16.1 | 16.2 |
| film | Component p | 4.5 | 4.5 | 4.5 | 6.1 | 4.1 |
| (non-volatile | Component h | 5.9 | 5.9 | 5.9 | 7.6 | 5.7 |
| component) | γUL | 40.3 | 40.3 | 40.3 | 38.5 | 31.3 |
| | Viscosity of non-volatile | 10 | 10 | 10 | 20 | 5 |
| | component | | | | | |
| | Ohnishi parameter | 3.2 | 3.2 | 3.2 | 6.1 | 3.5 |
| Imprint curable | Type | V-1 | V-1 | V-1 | V-1 | V-2 |
| composition | γResist | 33.0 | 33.0 | 33.0 | 33.0 | 34.0 |
| | Component d | 18.1 | 18.1 | 18.1 | 18.1 | 18.1 |
| | Component p | 4.5 | 4.5 | 4.5 | 4.5 | 4.5 |
| | Component h | 5.9 | 5.9 | 5.9 | 5.9 | 5.9 |
| | Ohnishi parameter | 3.5 | 3.5 | 3.5 | 3.5 | 3.5 |
| Kit | ΔHSP | 0.00 | 0.00 | 0.00 | 4.63 | 3.83 |
| | Δγ (γUL − γResist) | 7.3 | 7.3 | 7.3 | 5.5 | −2.7 |
| | Difference between | 0.3 | 0.3 | 0.3 | 2.6 | 0.0 |
| | Ohnishi parameters | | | | | |

| | | | | | |
|---|---|---|---|---|---|
| Film thickness of underlayer film (nm) | 21 | 8 | 3 | 8 | 0.1 |
| Film thickness stability of underlayer | B | B | A | C | D |
| film | | | | | |
| Wettability of IJ liquid droplets | A | A | A | C | D |
| Residual film uniformity | B | A | B | D | D |
| Processing resistance | B | A | A | D | B |

TABLE 3

| | | | Comparative | Comparative | Comparative | Comparative | Comparative | Comparative |
|---|---|---|---|---|---|---|---|---|
| | Viscosity at | Boiling | Example | Example | Example | Example | Example | Example |
| | 23° C. | point | 3 | 4 | 5 | 6 | 7 | 8 |
| A-1 | 10 | 330 | | | 0.3 | | 0.2 | |
| A-2 | 110 | 410 | | | | | | |
| A-3 | 63 | 440 | | | | | | |
| A-4 | 46 | 400 | | | | | | |
| A-5 | 15 | 320 | | | | | | |
| A-6 | 1050 | 530 | | | | | | 0.3 |
| A-7 | 22 | 330 | | | | | | |
| A-8 | 20 | 360 | | | | | | |
| A-9 | 5 | 250 | | | | | | |
| A-10 | 6 | 290 | 0.3 | 0.4 | | | | |
| A-11 | 10 | 330 | | | | 0.3 | | |
| A-12 | 1450 | 400 | | | | | | |
| A-13 | Solid | 610 | | | | | | |
| A-14 | 148 | 350 | | | | | | |
| B-1 | 120 | — | | | | | | |
| B-2 | 111 | — | | | | | 0.1 | |
| B-3 | Solid | — | | | | | | |
| B-4 | 12 | — | | | | | | |
| B-5 | 8 | 200 | | | | | | |
| C-1 | | 121 | 99.7 | 99.6 | 99.7 | 99.7 | 99.7 | 99.7 |
| C-2 | | 126 | | | | | | |
| C-3 | | 146 | | | | | | |
| C-4 | | 156 | | | | | | |
| Baking conditions | | | 60° C./ | 30° C./ | 60° C./ | 60° C./ | 60° C./ | 60° C./ |
| | | | 1 min | 1 min | 1 min | 1 min | 1 min | 1 min |
| Underlayer | Component d | | 16.4 | 16.4 | 18.1 | 16.4 | 17.6 | 17.7 |
| film | Component p | | 4.6 | 4.6 | 4.5 | 3.9 | 4.3 | 5.7 |
| (non-volatile | Component h | | 6.1 | 6.1 | 5.9 | 5.2 | 6 | 5.6 |
| component) | γUL | | 34.8 | 34.8 | 40.3 | 36.4 | 38.1 | 38.0 |
| | Viscosity of non-volatile | | 6 | 6 | 10 | 10 | 49 | 1050 |
| | component | | | | | | | |
| | Ohnishi parameter | | 4.3 | 4.3 | 3.2 | 3.3 | 3.1 | 3.3 |
| Imprint | Type | | V-3 | V-3 | V-5 | V-4 | V-1 | V-3 |
| curable | γResist | | 35.0 | 35.0 | 38.0 | 33.0 | 33.0 | 35.0 |
| composition | Component d | | 18.1 | 18.1 | 18.1 | 16.2 | 18.1 | 18.1 |
| | Component p | | 4.5 | 4.5 | 4.5 | 4.1 | 4.5 | 4.5 |
| | Component h | | 5.9 | 5.9 | 5.9 | 5.7 | 5.9 | 5.9 |
| | Ohnishi parameter | | 3.0 | 3.0 | 3.2 | 3.5 | 3.5 | 3.0 |
| Kit | ΔHSP | | 3.41 | 3.41 | 0.00 | 0.67 | 1.02 | 1.47 |
| | Δγ (γUL − γResist) | | −0.2 | −0.2 | 2.3 | 3.4 | 5.1 | 3.0 |
| | Difference between | | 1.3 | 1.3 | 0.0 | 0.2 | 0.4 | 0.3 |
| | Ohnishi parameters | | | | | | | |
| Film thickness of underlayer film (nm) | | | 0.1 | 8 | 8 | 8 | 8 | 8 |
| Film thickness stability of underlayer | | | D | D | A | B | A | A |
| film | | | | | | | | |
| Wettability of IJ liquid droplets | | | D | C | C | C | C | C |
| Residual film uniformity | | | D | D | C | C | C | C |
| Processing resistance | | | C | C | C | C | C | C |
| | | | | Comparative | Comparative | Comparative | Comparative | Comparative |
| | | Viscosity at | Boiling | Example | Example | Example | Example | Example |
| | | 23° C. | point | 9 | 10 | 11 | 12 | 13 |
| | A-1 | 10 | 330 | | | | | |
| | A-2 | 110 | 410 | | | | | |
| | A-3 | 63 | 440 | | | 0.3 | | |
| | A-4 | 46 | 400 | | | | | |
| | A-5 | 15 | 320 | | | | | |
| | A-6 | 1050 | 530 | | | | | |
| | A-7 | 22 | 330 | | | | | |
| | A-8 | 20 | 360 | | | | | 0.3 |
| | A-9 | 5 | 250 | | | | | |
| | A-10 | 6 | 290 | | | | | |
| | A-11 | 10 | 330 | | | | | |
| | A-12 | 1450 | 400 | 0.2 | | | | |
| | A-13 | Solid | 610 | | 0.2 | | | |
| | A-14 | 148 | 350 | | | | | |
| | B-1 | 120 | — | | | | | |
| | B-2 | 111 | — | | | | | |
| | B-3 | Solid | — | | | | | |
| | B-4 | 12 | — | | | | | |
| | B-5 | 8 | 200 | | | | 0.3 | |
| | C-1 | | 121 | 99.8 | 99.8 | 99.7 | 99.7 | 99.7 |
| | C-2 | | 126 | | | | | |
| | C-3 | | 146 | | | | | |
| | C-4 | | 156 | | | | | |

| Baking conditions | | 60° C./ | 60° C.. | 60° C./ | 60° C./ | 60° C./ |
|---|---|---|---|---|---|---|
| | | 1 min | 1 min | 1 min | 1 min | 1 min |
| Underlayer | Component d | 17.1 | 18.5 | 19.1 | 16.5 | 16.1 |
| film | Component p | 12 | 3.8 | 5.7 | 5.9 | 6.1 |
| (non-volatile | Component h | 9.3 | 4.2 | 6.2 | 77 | 7.6 |
| component) | γUL | 39.8 | — | 39.8 | 40.3 | 38.5 |
| | Viscosity of non-volatile | 1450 | — | 63 | 8 | 20 |
| | component | | | | | |
| | Ohnishi parameter | 5.2 | 2.5 | 2.9 | 5.8 | 6.1 |
| Imprint | Type | V-1 | V-2 | V-4 | V-1 | V-4 |
| curable | γResist | 33.0 | 34.0 | 32.0 | 33.0 | 32.0 |
| composition | Component d | 181 | 18.1 | 16.2 | 18.1 | 16.2 |
| | Component p | 4.5 | 4.5 | 4.1 | 4.5 | 4.1 |
| | Component h | 5.9 | 5.9 | 5.7 | 5.9 | 5.7 |
| | Ohnishi parameter | 3.5 | 3.5 | 3.6 | 3.5 | 3.6 |
| Kit | ΔHSP | 8.47 | 2.00 | 6.04 | 3.93 | 2.77 |
| | Δγ (γUL − γResist) | 6.8 | — | 7.8 | 7.3 | 6.5 |
| | Difference between | 1.7 | 1.0 | 0.7 | 2.3 | 2.5 |
| | Ohnishi parameters | | | | | |

| | | | | | |
|---|---|---|---|---|---|
| Film thickness of underlayer film (nm) | 8 | 8 | 8 | 8 | 8 |
| Film thickness stability of underlayer | A | A | A | D | C |
| film | | | | | |
| Wettability of IJ liquid droplets | D | D | C | C | C |
| Residual film uniformity | D | D | C | C | C |
| Processing resistance | C | C | B | C | C |

TABLE 4

| | | | Example | Example | Example | Example |
|---|---|---|---|---|---|---|
| | Viscosity at 23° C. | Boiling point | 20 | 21 | 22 | 23 |
| A-1 | 10 | 330 | 0.3 | | 0.3 | |
| A-2 | 110 | 410 | | 0.25 | | |
| A-3 | 63 | 440 | | | | |
| A-4 | 46 | 400 | | | | 0.25 |
| A-5 | 15 | 320 | | | | |
| A-6 | 1050 | 530 | | | | |
| A-7 | 22 | 330 | | | | |
| A-8 | 20 | 360 | | | | |
| A-9 | 5 | 250 | | | | |
| A-10 | 6 | 290 | | | | |
| A-11 | 10 | 330 | | | | |
| A-12 | 1450 | 400 | | | | |
| A-13 | Solid | 610 | | | | |
| A-14 | 148 | 350 | | | | |
| B-1 | 120 | — | | 0.05 | | 0.05 |
| B-2 | 111 | — | | | | |
| B-3 | Solid | — | | | | |
| B-4 | 12 | — | | | | |
| B-5 | 8 | 200 | | | | |
| C-1 | | 121 | 99.7 | 99.7 | 99.7 | 99.7 |
| C-2 | | 126 | | | | |
| C-3 | | 146 | | | | |
| C-4 | | 156 | | | | |

| Baking conditions | | 60° C./ | 60° C./ | 60° C./ | 60° C./ |
|---|---|---|---|---|---|
| | | 1 min | 1 min | 1 min | 1 min |
| Underlayer | Component d | 18.1 | 18.6 | 18.1 | 18.1 |
| film | Component p | 4.5 | 5.1 | 4.5 | 4.8 |
| (non-volatile | Component h | 5.9 | 5.6 | 5.9 | 6.5 |
| component) | γUL | 40.3 | 42.1 | 40.3 | 40.5 |
| | Viscosity of non-volatile component | 10 | 110 | 10 | 46 |
| | Ohnishi parameter | 3.2 | 2.9 | 3.2 | 3.5 |
| Imprint | Type | V-6 | V-6 | V-7 | V-7 |
| curable | γResist | 34.0 | 34.0 | 34.0 | 34.0 |
| composition | Component d | 18.1 | 18.1 | 18.1 | 18.1 |
| | Component p | 4.5 | 4.5 | 4.5 | 4.5 |
| | Component h | 5.9 | 5.9 | 5.9 | 5.9 |
| | Ohnishi parameter | 3.5 | 3.5 | 3.5 | 3.5 |
| Kit | ΔHSP | 0.00 | 1.20 | 0.00 | 0.67 |
| | Δγ (γUL − γResist) | 6.3 | 8.1 | 6.3 | 6.5 |
| | Difference between Ohnishi parameters | 0.3 | 0.6 | 0.3 | 0.0 |

| | | | | |
|---|---|---|---|---|
| Film thickness of underlayer film (nm) | 8 | 8 | 8 | 8 |
| Film thickness stability of underlayer film | A | A | A | A |
| Wettability of IJ liquid droplets | A | A | A | A |
| Residual film uniformity | A | A | A | A |
| Processing resistance | A | A | A | A |

TABLE 5

| | Boiling | | | | | | | |
|---|---|---|---|---|---|---|---|---|
| | point | V-1 | V-2 | V-3 | V-4 | V-5 | V-6 | V-7 |
| A-1 | 329 | 60 | 63 | 50 | | 100 | 50 | 60 |
| A-9 | 248.5 | 20 | | | | | | |
| 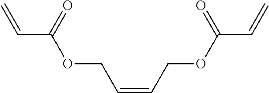 | 251 | | 22 | | | | 35 | 25 |
| A-10 | 283 | | | | 50 | | | |
| 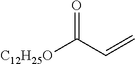 | 296.5 | 20 | 15 | | | | 15 | 15 |
| 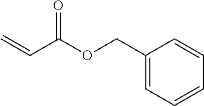 | 231.9 | | | 40 | 40 | | | |
| 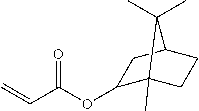 | 246 | | | 10 | 10 | | | |
| B-3 | | 2 | 2 | 2 | 2 | 2 | 2 | 2 |
| B-4 | | | 2 | 2 | 2 | 2 | 2 | 2 |
| 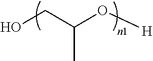 | | 3 | | | | | | |
| 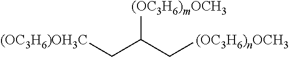 | | | 3 | | | | 3 | |
| 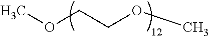 | | | | 1 | | 3 | | |
| Fluorinated surfactant | | | | | 3 | | | |
| (Capstone FS-3100) | | | | | | | | |
| 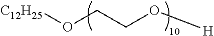 | | | | | | | | 3 |

| | | | | | | | |
|---|---|---|---|---|---|---|---|
| Viscosity at 23° C. (mPa · s) | 8 | 7 | 7 | <6 | 13 | 6 | 7 |
| Surface tension at 23° C. (mN/m) | 33.0 | 34.0 | 35.0 | 33.0 | 38.0 | 34.0 | 34.0 |
| Component d | 18.1 | 18.1 | 18.1 | 16.2 | 18.1 | 18.1 | 18.1 |
| Component p | 4.5 | 45 | 4.5 | 4.1 | 4.5 | 4.5 | 4.5 |
| Component h | 5.9 | 5.9 | 5.9 | 5.7 | 5.9 | 5.9 | 5.9 |
| Ohnishi parameter | 3.5 | 3.5 | 3.0 | 3.5 | 3.2 | 3.2 | 3.2 |

In Tables 1 to 5, the unit of viscosity is mPa-s and the unit of boiling point is ° C. γUL is the surface tension of the underlayer film, and the unit of surface tension is mN/m. The amount of each component in Tables 1 to 5 is a mass ratio. In Tables 1 to 5, component d, component p, and component h represent the dispersion term component, polar term component, and hydrogen bond term component of the HSP vector, respectively.

In the structural formulas in Table 5, n1 is 10 and m+n+1 is 10.

The compounds in Tables 1 to 5 are as follows.

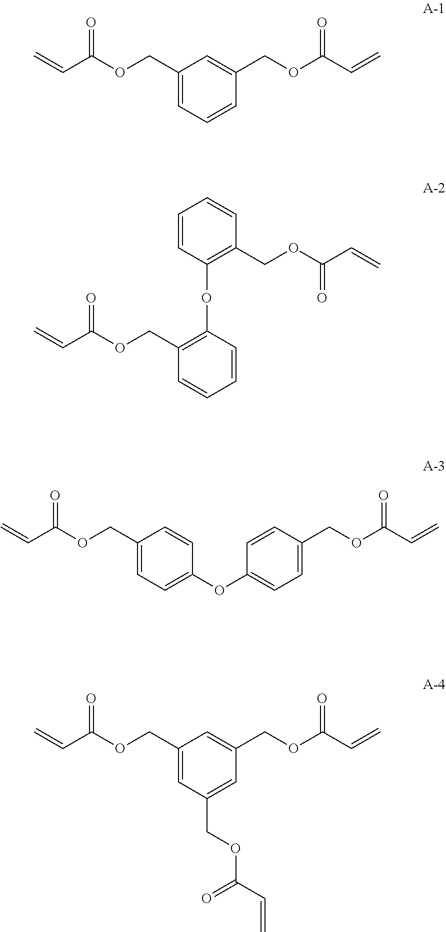

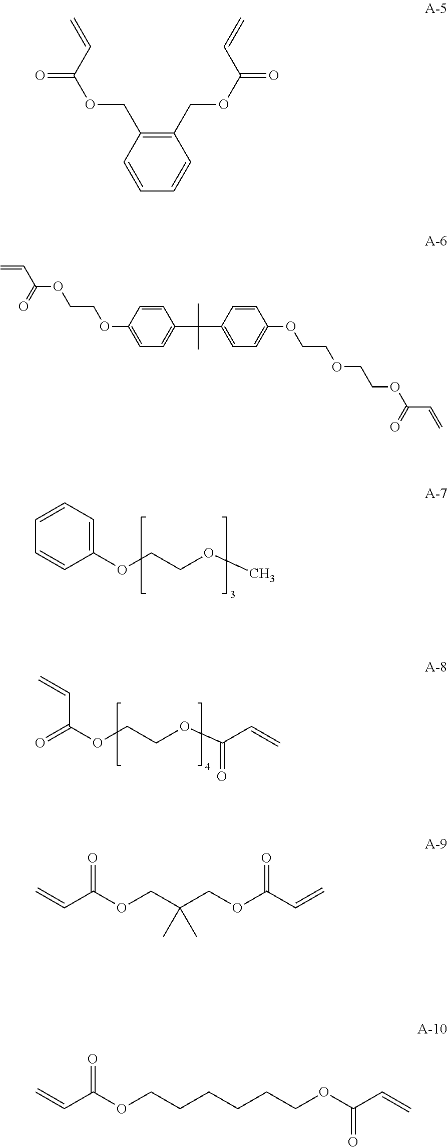

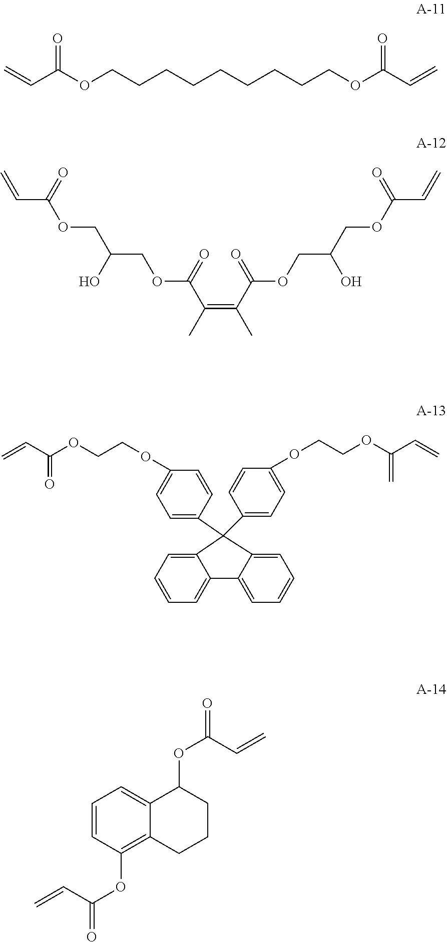

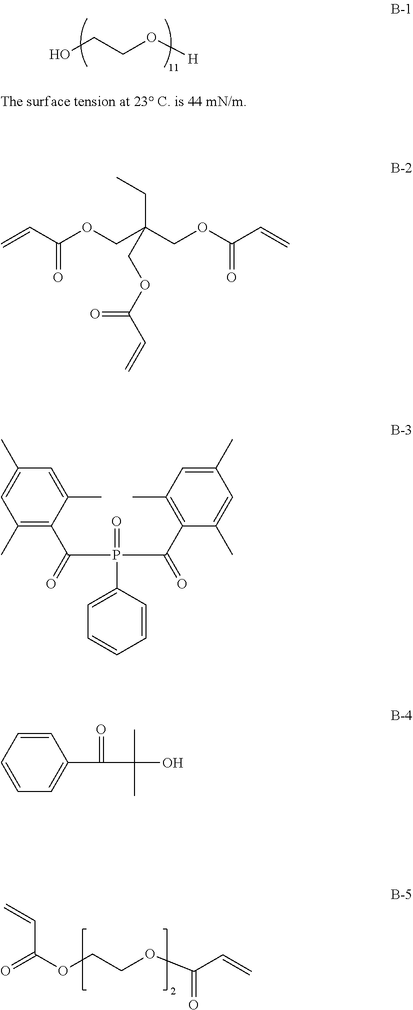

C-1: 1-methoxy-2-propanol (propylene glycol monomethyl ether) (boiling point: 121° C.)

C-2: butyl acetate (boiling point: 126° C.)

C-3: propylene glycol monomethyl ether acetate (boiling point: 146° C.)

C-4: cyclohexanone (boiling point: 156° C.)

As is apparent from the above results, the kit according to the embodiment of the present invention was capable of forming a uniform underlayer film and was excellent in the wettability of the curable composition for imprints (Examples 1 to 23). Furthermore, the kit which can provide the pattern exhibiting excellent residual film uniformity of the obtained cured product pattern and excellent etching resistance was obtained.

On the other hand, in kits of Comparative Examples (Comparative Examples 1, 9, and 11) not satisfying |ΔHSP|≤4.5 and kits of Comparative Examples (Comparative Examples 2 to 4) not satisfying γUL≥γResist, the wettability and the residual film uniformity were poor. Furthermore, the residual film uniformity and etching resistance tended to be inferior. In Comparative Example 10, the non-volatile component is solid.

In addition, by setting the boiling point of the component having the highest content, among the non-volatile components in the composition for forming an underlayer film for imprints, to 325° C. or higher, a kit having superior film thickness stability, wettability, and residual film uniformity was obtained (Comparison of Example 12 with Examples 1 to 11 and 20 to 23).

In addition, by setting the boiling point of the solvent contained in the composition for forming an underlayer film for imprints to 130° C. or lower, a kit having superior film thickness stability of the underlayer film and superior residual film uniformity was obtained (Comparison of Examples 13 and 14 with Examples 1 to 11 and 20 to 23).

By setting the thickness of the underlayer film to 3 nm or more, it became possible to further improve the wettability and the processing resistance (Comparison of Example 16 with Examples 1 to 11 and 20 to 23).

By setting the thickness of the underlayer film to 20 nm or less, it became possible to further improve the film thickness stability, the residual film uniformity, and the processing resistance (Comparison of Example 17 with Examples 1 to 11 and 20 to 23).

By setting the baking temperature to 40° C. or higher, it became possible to further improve the film thickness stability (Comparison of Example 18 with Examples 1 to 11 and 20 to 23).

By setting the baking temperature to 70° C. or lower, it became possible to further improve the residual film uniformity (Comparison of Example 19 with Examples 1 to 11 and 20 to 23).

### EXPLANATION OF REFERENCES

1: substrate
2: underlayer film
3: curable composition for imprints
4: mold
21: underlayer film
22: curable composition for imprints

What is claimed is:

1. A kit comprising a curable composition for imprints and a composition for forming an underlayer film for imprints, the kit satisfying all of the following A to C;
A: the composition for forming an underlayer film for imprints contains a compound that is liquid at 23° C. and has a boiling point of 300° C. or lower in a proportion of 99.0% by mass or more;
B: any of the following (1) to (3) is satisfied;
γUL−γResist≥3 and |ΔHSP|≤0.5, (1)
γUL−γResist≥5 and |ΔHSP|≤1.0, (2)
γUL−γResist≥6 and |ΔHSP|≤3.0, (3)
in the above formulae, γResist represents a surface tension at 23° C. of the curable composition for imprints, and γUL represents a surface tension at 23° C. of a composition comprised of the components excluding the compound that is liquid at 23° C. and has a boiling point of 300° C. or lower, in the composition for forming an underlayer film for imprints;
ΔHSP=(4.0×ΔD²+ΔP²+ΔH²)^{0.5}
wherein the ΔD is a difference between a dispersion term component of a Hansen solubility parameter vector of a component having the highest content in the curable composition for imprints and a dispersion term component of a Hansen solubility parameter vector of a component having the highest content in the composition comprised of the components excluding the compound that is liquid at 23° C. and has a boiling point of 300° C. or lower, in the composition for forming an underlayer film for imprints;
the ΔP is a difference between a polar term component of a Hansen solubility parameter vector of the component having the highest content in the curable composition for imprints and a polar term component of a Hansen solubility parameter vector of the component having the highest content in the composition comprised of the components excluding the compound that is liquid at 23° C. and has a boiling point of 300° C. or lower, in the composition for forming an underlayer film for imprints; and
the ΔH is a difference between a hydrogen bond term component of a Hansen solubility parameter vector of the component having the highest content in the curable composition for imprints and a hydrogen bond term component of a Hansen solubility parameter vector of the component having the highest content in the composition comprised of the components excluding the compound that is liquid at 23° C. and has a boiling point of 300° C. or lower, in the composition for forming an underlayer film for imprints,
C: the component having the highest content in the composition comprised of the components excluding the compound that is liquid at 23° C. and has a boiling point of 300° C. or lower, in the composition for forming an underlayer film for imprints, has a boiling point of higher than 300° C. and is liquid at 23° C.

2. The kit according to claim 1, wherein at least one contained in the composition comprised of the components excluding the compound that is liquid at 23° C. and has a boiling point of 300° C. or lower, in the composition for forming an underlayer film for imprints, is a compound having a group capable of reacting with the curable composition for imprints to form a covalent bond.

3. The kit according to claim 1, wherein the component having the highest content in the composition comprised of the components excluding the compound that is liquid at 23° C. and has a boiling point of 300° C. or lower, in the composition for forming an underlayer film for imprints, is a compound having a group capable of reacting with the curable composition for imprints to form a covalent bond.

4. The kit according to claim 2, wherein at least one of the compounds having a group capable of reacting with the curable composition for imprints to form a covalent bond is a compound containing an aromatic ring structure.

5. The kit according to claim 1, wherein the γUL is 38.0 mN/m or more.

6. The kit according to claim 1, wherein a viscosity at 23° C. of the composition comprised of the components excluding the compound that is liquid at 23° C. and has a boiling point of 300° C. or lower, in the composition for forming an underlayer film for imprints, is 5 to 1000 mPa·s.

7. The kit according to claim 1, wherein a difference between an Ohnishi parameter of the composition comprised of the components excluding the compound that is liquid at 23° C. and has a boiling point of 300° C. or lower, in the composition for forming an underlayer film for imprints, and an Ohnishi parameter of the curable composition for imprints is 0.5 or less; provided that the Ohnishi parameter is the sum of the number of carbon atoms, hydrogen atoms and oxygen atoms/(number of carbon atoms-number of oxygen atoms) for atoms constituting each composition.

8. The kit according to claim 1, wherein the component having the highest content among the compounds that are liquid at 23° C. and have a boiling point of 300° C. or lower, in the composition for forming an underlayer film for imprints, has a boiling point of 130° C. or lower.

9. The kit according to claim 1, wherein the composition for forming an underlayer film for imprints contains a photopolymerization initiator.

10. The kit according to claim 1, wherein the component having the highest content in the composition comprised of the components excluding the compound that is liquid at 23° C. and has a boiling point of 300° C. or lower, in the composition for forming an underlayer film for imprints, has a boiling point of 325° C. or higher.

11. A laminate formed from the kit according to claim 1, comprising:
an underlayer film formed from the composition for forming an underlayer film for imprints; and
an imprint layer formed from the curable composition for imprints and positioned on a surface of the underlayer film.

12. A method for producing a laminate using the kit according to claim 1, the method comprising:
applying the curable composition for imprints onto a surface of the underlayer film formed from the composition for forming an underlayer film for imprints.

13. The method for producing a laminate according to claim 12, wherein the curable composition for imprints is applied onto the surface of the underlayer film by an ink jet method.

14. The method for producing a laminate according to claim 12, further comprising:
a step of applying the composition for forming an underlayer film for imprints in a layered manner on a substrate; and
a step of heating the composition for forming an underlayer film for imprints applied in a layered manner at 40° C. to 70° C.

15. A method for producing a cured product pattern, using the kit according to claim 1, the method comprising:
an underlayer film forming step of applying a composition for forming an underlayer film for imprints onto a substrate to form an underlayer film;
an applying step of applying a curable composition for imprints onto a surface of the underlayer film;
a mold contact step of bringing the curable composition for imprints into contact with a mold having a pattern for transferring a pattern shape;
a light irradiation step of irradiating the curable composition for imprints with light to form a cured product; and
a mold release step of separating the cured product and the mold from each other.

16. A method for producing a circuit board, comprising:
a step of obtaining a cured product pattern by the production method according to claim 15.
